(19) United States
(12) Patent Application Publication
(10) Pub. No.: US 2025/0116932 A1
(43) Pub. Date: Apr. 10, 2025

(54) THIOL-CONTAINING PHOTORESIST COMPOSITIONS FOR EXTREME ULTRAVIOLET LITHOGRAPHY

(71) Applicant: Taiwan Semiconductor Manufacturing Co., Ltd., Hsinchu (TW)

(72) Inventors: Li-Po YANG, Hsinchu (TW); Wei-Han LAI, Hsinchu (TW); Kuan-Hsin LO, Hsinchu (TW); Ching-Yu CHANG, Hsinchu (TW)

(21) Appl. No.: 18/601,835

(22) Filed: Mar. 11, 2024

Related U.S. Application Data
(60) Provisional application No. 63/588,880, filed on Oct. 9, 2023.

(51) Int. Cl. G03F 7/039; C08F 212/14; C08F 220/18; C08F 220/38; G03F 7/038

(52) U.S. Cl. CPC G03F 7/039; C08F 212/22; C08F 212/24; C08F 212/30; C08F 220/1807; C08F 220/1808; C08F 220/38; G03F 7/038

(57) ABSTRACT

A method for manufacturing a semiconductor device includes forming a photoresist layer from a photoresist composition over a substrate. The photoresist layer is selectively exposed to actinic radiation to form a latent pattern and the latent pattern is developed by applying a developer to the selectively exposed photoresist layer to form a patterned photoresist. The photoresist composition includes a photoactive compound, a thiol-containing polymer comprising an aryl group and an acid labile group. The thiol group can crosslink the polymer via oxidative disulfide formation and/or thiol-ene/yne “click” reaction.

### PRIORITY CLAIM AND CROSS-REFERENCE

This application claims the benefit of U.S. Provisional Patent Application No. 63/588,880, filed Oct. 9, 2023, which is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for fabricating a semiconductor device, in accordance with some embodiments of the present disclosure.

FIGS. 2A-2G are cross-sectional views of a semiconductor device fabricated using the method of FIG. 1, in accordance with some embodiments of the present disclosure.

FIG. 3A illustrates a first exemplary scheme for crosslinking a thiol-containing polymer via oxidative disulfide formation, in accordance with some embodiment of the present disclosure.

FIG. 3B illustrates a second exemplary scheme for crosslinking a thiol-containing polymer using a crosslinker, in accordance with some embodiment of the present disclosure.

FIG. 3C illustrates a third exemplary scheme for crosslinking a thiol-ene polymer, in accordance with some embodiment of the present disclosure.

FIG. 4 illustrates exemplary crosslinkers, in accordance with some embodiments of the present disclosure.

FIG. 5 illustrates an exemplary scheme for crosslinking a thiol-free polymer via thiol-ene reaction, in accordance with some embodiment of the present disclosure.

FIG. 6A shows a structure of a polymer that is in an exposed region of a photoresist layer, in accordance with some embodiments of the present disclosure.

FIG. 6B shows a structure of the polymer that is in an unexposed region of the photoresist layer of FIG. 6A, in accordance with some embodiments of the present disclosure.

### DETAILED DESCRIPTION ANSON

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. System may be otherwise oriented (rotated 90 degrees or at other orientations) and the spatially relative descriptors used herein may likewise be interpreted accordingly.

“Alkyl” by itself or as part of another substituent, refers to a straight or branched hydrocarbon chain group consisting solely of carbon and hydrogen atoms, containing no unsaturation, having from one to twenty carbon atoms (C1-C20 alkyl), one to twelve carbon atoms (C1-C12 alkyl), one to eight carbon atoms (C1-C8 alkyl) or one to six carbon atoms (C1-C6 alkyl), and which is attached to the rest of the molecule by a single bond, e.g., methyl, ethyl, n-propyl, 1-methylethyl (iso-propyl), n-butyl, n-pentyl, 1,1-dimethylethyl (t-butyl), 3-methylhexy, 2-methylhexyl, and the like. Unless stated otherwise specifically in the specification, an alkyl group is optionally substituted.

“Alkylene” as used herein refers to a straight or branched divalent hydrocarbon chain linking the rest of the molecule to a radical group, consisting solely of carbon and hydrogen, containing no unsaturation, and having from one to twelve carbon atoms, e.g., methylene, ethylene, propylene, n-butylene, and the like. The alkylene chain is attached to the rest of the molecule through a single bond and to the radical group through a single bond. The points of attachment of the alkylene chain to the rest of the molecule and to the radical group can be through one carbon or any two carbons within the chain. Unless stated otherwise specifically in the specification, an alkylene group is optionally substituted.

“Alkene” as used herein refers to a straight or branched hydrocarbon chain consisting solely of carbon and hydrogen, containing at least one carbon-carbon double bond and having from two to twelve carbon atoms, e.g., ethene, propene, n-butene, and the like. Unless stated otherwise specifically in the specification, an alkene group is optionally substituted.

“Alkenylene” as used herein refers to a straight or branched divalent hydrocarbon chain linking the rest of the molecule to a radical group, consisting solely of carbon and hydrogen, containing at least one double bond, having from two to twelve carbon atoms, e.g., ethenylene, propenylene, n-butenylene, and the like. The alkenylene chain is attached to the rest of the molecule through a single bond and to the radical group through a double bond or a single bond. The points of attachment of the alkenylene chain to the rest of the molecule and to the radical group can be through one carbon or any two carbons within the chain. Unless stated otherwise specifically in the specification, alkenylene is optionally substituted.

“Alkyne” as used herein refers to a straight or branched hydrocarbon chain consisting solely of carbon and hydrogen, containing at least one carbon-carbon triple bond and having from two to twelve carbon atoms, e.g., ethyne, propyne, n-butyne, and the like.

“Alkynylene” as used herein refers to a straight or branched divalent hydrocarbon chain linking the rest of the molecule to a radical group, consisting solely of carbon and hydrogen, containing at least one triple bond, having from two to twelve carbon atoms, e.g., ethynylene, propynylene, n-butynylene, and the like. The alkynylene chain is attached to the rest of the molecule through a single bond and to the radical group through a triple bond or a single bond. The points of attachment of the alkynylene chain to the rest of the molecule and to the radical group can be through one carbon or any two carbons within the chain. Unless stated otherwise specifically in the specification, alkynylene is optionally substituted.

“Alkoxy” as used herein refers to an O-alkyl group in which the alkyl is defined above. Unless stated otherwise specifically in the specification, an alkoxy group is optionally substituted.

“Alkylether” as used herein refers to any alkyl group as defined above, wherein at least one carbon-carbon bond is replaced with a carbon-oxygen bond. The carbon-oxygen bond may be on the terminal end (as in an alkoxy group) or the carbon oxygen bond may be internal (i.e., C—O—C). Alkylethers include at least one carbon oxygen bond, but may include more than one. For example, polyethylene glycol (PEG) is included within the meaning of alkylether. Unless stated otherwise specifically in the specification, an alkylether group is optionally substituted.

“Cycloalkyl” as used herein refers to a stable non-aromatic monocyclic or polycyclic carbocyclic radical consisting solely of carbon and hydrogen atoms, which may include fused or bridged ring systems, having from three to fifteen carbon atoms, preferably having from three to ten carbon atoms, and which is saturated or unsaturated and attached to the rest of the molecule by a single bond. Monocyclic radicals include, for example, cyclopropyl, cyclobutyl, cyclopentyl, cyclohexyl, cycloheptyl, and cyclooctyl. Polycyclic radicals include, for example, adamantyl, norbornyl, decalinyl, 7,7-dimethyl-bicyclo[2.2.1]heptanyl, and the like. “Cycloalkylene” is a divalent or multivalent cycloalkyl, which typically connects one portion a molecule to a radical group or connects two or more radical groups. Unless otherwise stated specifically in the specification, a cycloalkyl (or cycloalkylene) group is optionally substituted.

“Heteroalkyl” as used herein refers to an alkyl group, as defined above, comprising at least one heteroatom (e.g., N, O, P or S) within the alkyl group or at a terminus of the alkyl group. In some embodiments, the heteroatom is within the alkyl group (i.e., the heteroalkyl comprises at least one carbon-[heteroatom]x-carbon bond, where x is 1, 2 or 3). In other embodiments, the heteroatom is at a terminus of the alkyl group and thus serves to join the alkyl group to the remainder of the molecule (e.g., M1-H-A), where M1 is a portion of the molecule, H is a heteroatom and A is an alkyl group). Unless stated otherwise specifically in the specification, a heteroalkyl group is optionally substituted. Exemplary heteroalkyl groups include ethylene oxide (e.g., polyethylene oxide), optionally including phosphorous-oxygen bonds, such as phosphodiester bonds.

“Heteroalkylene” as used herein refers to an alkylene group, as defined above, comprising at least one heteroatom (e.g., N, O, P or S) within the alkylene chain or at a terminus of the alkylene chain. In some embodiments, the heteroatom is within the alkylene chain (i.e., the heteroalkylene comprises at least one carbon-heteroatom-carbon bond). In other embodiments, the heteroatom is at a terminus of the alkylene and thus serves to join the alkylene to the remainder of the molecule (e.g., M1-H-A-M2, where M1 and M2 are portions of the molecule, H is a heteroatom and A is an alkylene). Unless stated otherwise specifically in the specification, a heteroalkylene group is optionally substituted.

“Heteroalkenyl” as used herein is a heteroalkyl, as defined above, comprising at least one carbon-carbon double bond. Unless stated otherwise specifically in the specification, a heteroalkenyl group is optionally substituted.

“Heteroalkynyl” as used herein is a heteroalkyl comprising at least one carbon-carbon triple bond. Unless stated otherwise specifically in the specification, a heteroalkynyl group is optionally substituted.

“Carbocyclic” refers to a stable 3- to 18-membered aromatic or non-aromatic ring comprising 3 to 18 carbon atoms. Unless stated otherwise specifically in the specification, a carbocyclic ring may be a monocyclic, bicyclic, tricyclic or tetracyclic ring system, which may include fused or bridged ring systems, and may be partially or fully saturated. Non-aromatic carbocyclyl radicals include cycloalkyl, while aromatic carbocyclyl radicals include aryl. Unless stated otherwise specifically in the specification, a carbocyclic group is optionally substituted.

“Aryl” employed alone or in combination with other terms (e.g., aryloxy, arylalkyl) refers to a ring system comprising at least one carbocyclic aromatic ring. In some embodiments, an aryl comprises from 6 to 18 carbon atoms. The aryl ring may be a monocyclic, bicyclic, tricyclic or tetracyclic ring system, which may include fused or bridged ring systems. Aryls include, but are not limited to, aryls derived from aceanthrylene, acenaphthylene, acephenanthrylene, anthracene, azulene, benzene, chrysene, fluoranthene, fluorene, as-indacene, s-indacene, indane, indene, naphthalene, phenalene, phenanthrene, pleiadene, pyrene, and triphenylene. Unless stated otherwise specifically in the specification, an aryl group is optionally substituted.

“Arylene” as used herein refers to a bifunctional aromatic moiety containing one to five aromatic rings. Unless stated otherwise specifically in the specification, an arylene group is optionally substituted.

“Heterocyclic” as used herein refers to a stable 3- to 18-membered aromatic or non-aromatic ring comprising one to twelve carbon atoms and from one to six heteroatoms selected from the group consisting of nitrogen, oxygen and sulfur. Unless stated otherwise specifically in the specification, the heterocyclic ring may be a monocyclic, bicyclic, tricyclic or tetracyclic ring system, which may include fused or bridged ring systems; and the nitrogen, carbon or sulfur atoms in the heterocyclic ring may be optionally oxidized; the nitrogen atom may be optionally quaternized; and the heterocyclic ring may be partially or fully saturated. Examples of aromatic heterocyclic rings are listed below in the definition of heteroaryls (i.e., heteroaryl being a subset of heterocyclic). Examples of non-aromatic heterocyclic rings include, but are not limited to, dioxolanyl, thienyl[1,3]dithianyl, decahydroisoquinolyl, imidazolinyl, imidazolidinyl, isothiazolidinyl, isoxazolidinyl, morpholinyl, octahydroindolyl, octahydroisoindolyl, 2-oxopiperazinyl, 2-oxopiperidinyl, 2-oxopyrrolidinyl, oxazolidinyl, piperidinyl, piperazinyl, 4-piperidonyl, pyrrolidinyl, pyrazolidinyl, pyrazolopyrimidinyl, quinuclidinyl, thiazolidinyl, tetrahydrofuryl, trioxanyl, trithianyl, triazinanyl, tetrahydropyranyl, thiomorpholinyl, thiamorpholinyl, 1-oxo-thiomorpholinyl, and 1,1-dioxo-thiomorpholinyl. Unless stated otherwise specifically in the specification, a heterocyclic group is optionally substituted.

“Heteroaryl” as used herein refers to a 5- to 14-membered ring system comprising one to thirteen carbon atoms, one to six heteroatoms selected from the group consisting of nitrogen, oxygen and sulfur, and at least one aromatic ring. For purposes of certain embodiments of this disclosure, the heteroaryl radical may be a monocyclic, bicyclic, tricyclic or tetracyclic ring system, which may include fused or bridged ring systems; and the nitrogen, carbon or sulfur atoms in the heteroaryl radical may be optionally oxidized; the nitrogen atom may be optionally quaternized. Examples include, but are not limited to, azepinyl, acridinyl, benzimidazolyl, benzthiazolyl, benzindolyl, benzodioxolyl, benzofuranyl, benzooxazolyl, benzothiazolyl, benzothiadiazolyl, benzo[b][1,4]dioxepinyl, 1,4-benzodioxanyl, benzonaphthofuranyl, benzoxazolyl, benzodioxolyl, benzodioxinyl, benzopyranyl, benzopyranonyl, benzofuranyl, benzofuranonyl, benzothienyl (benzothiophenyl), benzotriazolyl, benzo[4,6]imidazo[1,2-a]pyridinyl, benzoxazolinonyl, benzimidazolthionyl, carbazolyl, cinnolinyl, dibenzofuranyl, dibenzothiophenyl, furanyl, furanonyl, isothiazolyl, imidazolyl, indazolyl, indolyl, indazolyl, isoindolyl, indolinyl, isoindolinyl, isoquinolyl, indolizinyl, isoxazolyl, naphthyridinyl, oxadiazolyl, 2-oxoazepinyl, oxazolyl, oxiranyl, 1-oxidopyridinyl, 1-oxidopyrimidinyl, 1-oxidopyrazinyl, 1-oxidopyridazinyl, 1-phenyl-1H-pyrrolyl, phenazinyl, phenothiazinyl, phenoxazinyl, phthalazinyl, pteridinyl, pteridinonyl, purinyl, pyrrolyl, pyrazolyl, pyridinyl, pyridinonyl, pyrazinyl, pyrimidinyl, pryrimidinonyl, pyridazinyl, pyrrolyl, pyrido[2,3-d]pyrimidinonyl, quinazolinyl, quinazolinonyl, quinoxalinyl, quinoxalinonyl, quinolinyl, isoquinolinyl, tetrahydroquinolinyl, thiazolyl, thiadiazolyl, thieno[3,2-d]pyrimidin-4-onyl, thieno[2,3-d]pyrimidin-4-onyl, triazolyl, tetrazolyl, triazinyl, and thiophenyl (i.e., thienyl). Unless stated otherwise specifically in the specification, a heteroaryl group is optionally substituted.

“Heteroarylene” as used herein refers to a divalent aromatic hydrocarbon of 6-20 carbon atoms containing N, S, O or P.

“halo” or “halogen” as used herein includes fluorine, chlorine, bromine, and iodine.

“Halogenated” means having one or more halogen atoms, e.g., fluorine, chlorine, bromine, or iodine atoms, incorporated into the above groups.

“fluorinated” means having one or more fluorine atoms incorporated into the above groups, e.g., where a fluoroalkyl group is indicated, the group includes a single fluorine atom, a difluoromethylene group, a trifluoromethyl group, a combination of these, or is a perfluorinated group (e.g., CF₃, C₂F5, C₃F₇, C₄F₉, etc.).

The term “substituted” as used herein means any of the above groups (e.g., alkyl, alkylene, alkenyl, alkynyl, heteroalkylene, heteroalkenyl, heteroalkynyl, alkoxy, heteroalkyl, carbocyclic, cycloalkyl, aryl, arylene, heterocyclic, heteroaryl, and/or heteroarylene) wherein at least one hydrogen atom (e.g., 1, 2, 3 or all hydrogen atoms) is replaced by a bond to a non-hydrogen atoms such as, but not limited to: a halogen atom such as F, Cl, Br, and I; an oxygen atom in groups such as hydroxyl groups, alkoxy groups, and ester groups; a sulfur atom in groups such as thiol groups, thioalkyl groups, sulfone groups, sulfonyl groups, and sulfoxide groups; a nitrogen atom in groups such as amines, amides, alkylamines, dialkylamines, arylamines, alkylarylamines, diarylamines, N-oxides, imides, and enamines; a silicon atom in groups such as trialkylsilyl groups, dialkylarylsilyl groups, alkyldiarylsilyl groups, and triarylsilyl groups; and other heteroatoms in various other groups. “Substituted” also means any of the above groups in which one or more hydrogen atoms are replaced by a higher-order bond (e.g., a double- or triple-bond) to a heteroatom such as oxygen in oxo, carbonyl, carboxyl, and ester groups; and nitrogen in groups such as imines, oximes, hydrazones, and nitriles. For example, “substituted” includes any of the above groups in which one or more hydrogen atoms are replaced with —NR_{g}Rₕ, —NR_{g}C(═O)Rₕ, —NR_{g}C(═O)NR_{g}Rₕ, —NR_{g}C(═O)ORₕ, —NR_{g}SO₂Rₕ, —OC(═O)NR_{g}Rₕ, —OR_{g}, —SR_{g}, —SOR_{g}, —SO₂R_{g}, —OSO₂R_{g}, —SO₂OR_{g}, ═NSO₂R_{g}, and —SO₂NR_{g}Rₕ. “Substituted” also means any of the above groups in which one or more hydrogen atoms are replaced with —C(═O)R_{g}, —C(═O)OR_{g}, —C(═O)NR_{g}Rₕ, —CH₂SO₂R_{g}, and —CH₂SO₂NR_{g}Rₕ. In the foregoing, R_{g} and Rₕ are the same or different and independently hydrogen, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl, and/or heteroarylalkyl. “Substituted” further means any of the above groups in which one or more hydrogen atoms are replaced by a bond to an amino, cyano, hydroxyl, imino, nitro, oxo, thioxo, halo, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl, and/or heteroarylalkyl group. In addition, each of the foregoing substituents may also be optionally substituted with one or more of the above substituents.

IC fabrication uses one or more photolithography processes to transfer geometric patterns to a film or substrate. Geometric shapes and patterns on a semiconductor form the complex structures that allow the dopants, electrical properties and wires to complete a circuit and fulfill a technological purpose. In a photolithography process, a photoresist is applied as a thin film to a substrate, and subsequently exposed to one or more types of radiation or light through a photomask. The photomask contains clear and opaque features that define a pattern which is to be created in the photoresist layer. Areas in the photoresist exposed to light transmitted through the photomask are made either soluble or insoluble in a specific type of solution known as a developer. In the case when the exposed areas are soluble, a positive image of the photomask is produced in the photoresist and this type of photoresist is called a positive photoresist. On the other hand, if the unexposed areas are dissolved by the developer, a negative image results in the photoresist and this type of photoresist is called a negative photoresist. The developer removes the more soluble areas, leaving the patterned photoresist in place. The resist pattern is then used as an etch mask in subsequent etching processes, transferring the pattern to an underlying material layer, thereby replicating the mask pattern in the underlying material layer. Alternatively, the resist pattern is then used as an ion implantation mask in subsequent ion implantation processes applied to the underlying material layer, such as an epitaxial semiconductor layer.

The quality of the resist pattern influences the quality of the final ICs. As the critical dimension (CD) of the integrated circuit continues to shrink, the ability of the photoresist to accurately replicate the features of the photomask becomes increasingly challenging due to image blur, which is caused by photoacid diffusion during the photolithography process. Specifically, the photogenerated acid may migrate away from the exposed areas and into the unexposed areas during photolithography, where it can trigger unwanted reactions.

Raising the glass transition temperature (Tg) of a photoresist polymer typically reduces the acid diffusion length. This is because the diffusivity of the acid in the photoresist polymer decreases when the polymer is in a glassy solid state. Photoresist polymers characterized by higher glass transition temperatures are therefore better suited to inhibit acid diffusion, resulting in improved pattern resolution and reduced line width roughness (LWR). Crosslinking has been demonstrated to effectively increase molecular weights and glass transition temperatures of resist polymers.

Phenolic groups are commonly utilized as crosslinking groups in existing photoresist polymers. However, the weak acidity of the phenol group (pKa=9.95) necessitates an additional baking step to initiate the crosslinking reaction between phenol groups at temperatures ranging from 100° C. to 150° C. Furthermore, the baking temperature needs to be lower than the decompositions temperature of the acid labile group (ALG) in the photoresist polymer to prevent the cleavage of the ALG at the crosslinking stage. Since higher baking temperature leads to higher crosslinking reaction efficiency, such control over the baking temperature may limit the efficiency of the crosslinking reaction between phenol groups.

In embodiments of the present disclosure, photoresist compositions comprising a thiol-containing polymer or a thiol-containing crosslinker are provided for improving crosslink efficiency of EUV lithography. Thiol, with a pKa value of 6.62, exhibits higher acidity compared to phenol, commonly used as a crosslinking group in existing EUV photoresist compositions. The higher acidity of thiol results in a more complete thiol-thiol crosslinking reaction compared to the phenol-phenol crosslinking reaction under the same baking temperature. The enhanced crosslinking efficiency leads to an increase in molecular weights of the crosslinked photoresist polymers, resulting in higher glass transition temperatures. The elevated glass transition temperatures of the crosslinked photoresist polymers allow for effectively limiting the photoacid diffusion length during the photolithography process. This, in turn, enables the fabrication of patterned features with higher resolution and reduced line width roughness (LWR). As a result, the quality of the resist pattern is improved, which helps to improve the yield and the reliability of the IC.

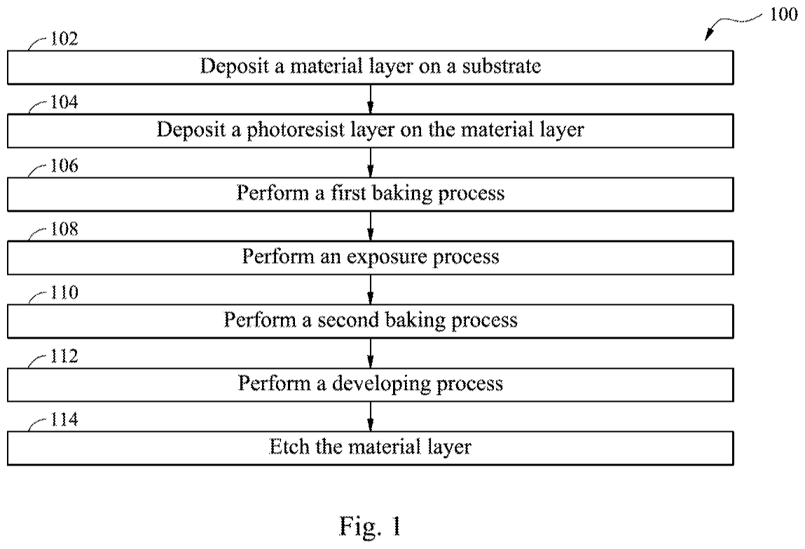

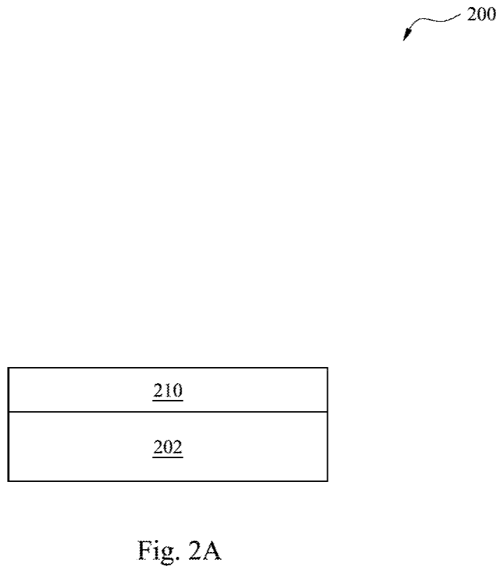

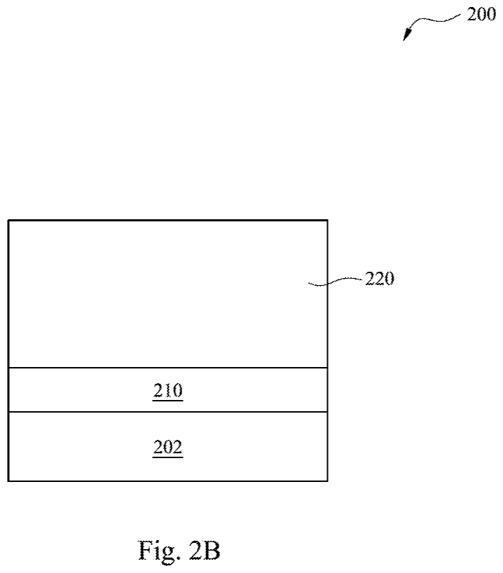

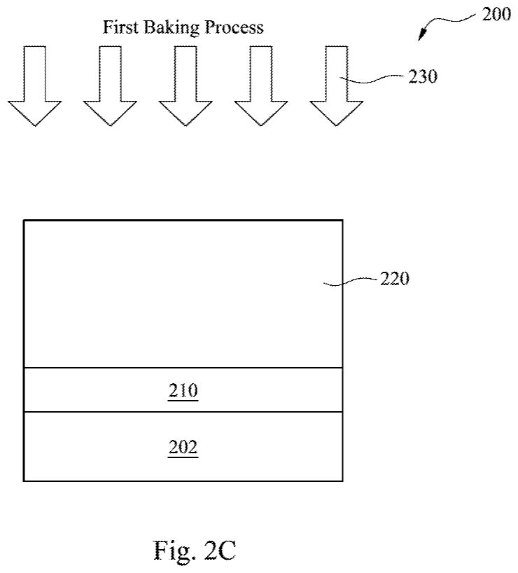

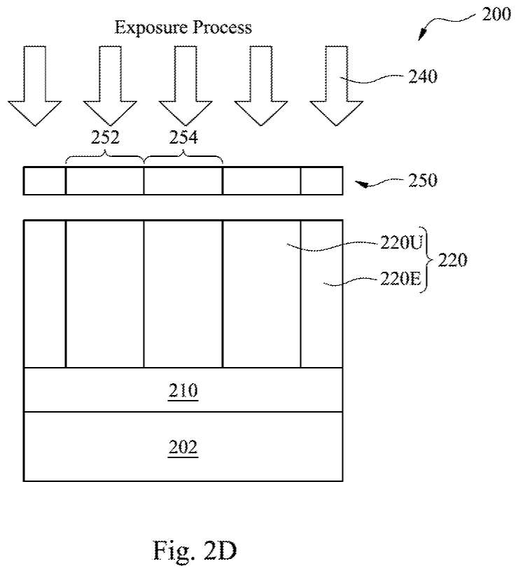

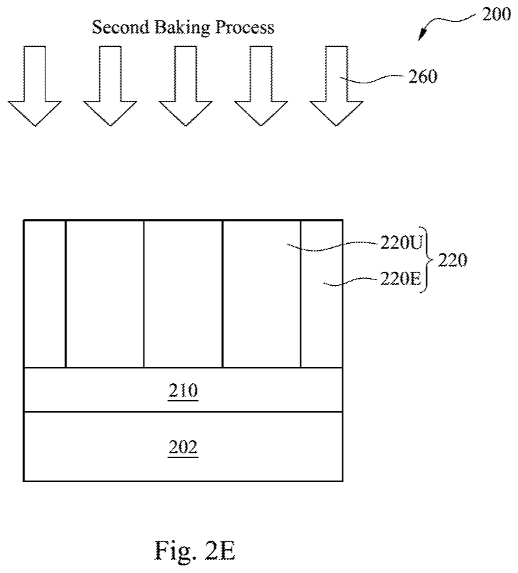

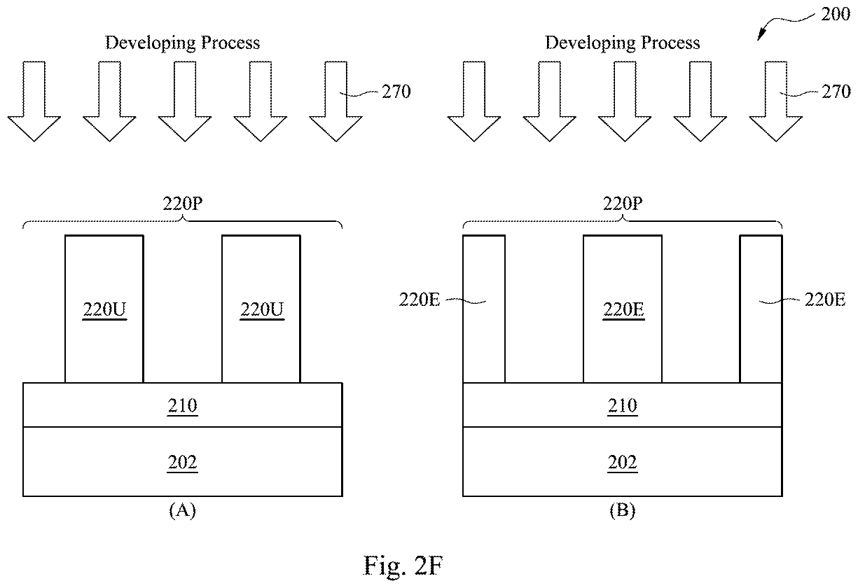

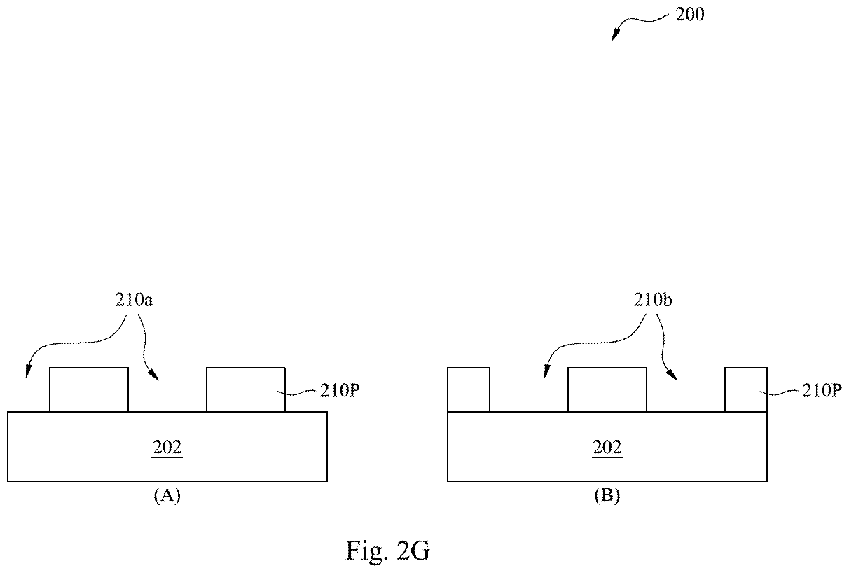

FIG. 1 is a flowchart illustrating a method 100 of fabricating a semiconductor device 200, in accordance with some embodiments of the present disclosure. FIGS. 2A through 2G are cross-sectional views of a semiconductor device 200 at various fabrication stages in accordance with some embodiments of the present disclosure. The method 100 is described below in conjunction with FIG. 1 and FIGS. 2A through 2G where the semiconductor device 200 is fabricated by using embodiments of the method 100. It is understood that additional steps can be provided before, during, and after the method 100, and some of the steps described below can be replaced or eliminated, for additional embodiments of the method. It is further understood that additional features can be added in the semiconductor device 200, and some of the features described below can be replaced or eliminated, for additional embodiments of the semiconductor device 200.

The semiconductor device 200 may be an intermediate structure during the fabrication of an IC, or a portion thereof. The IC may include logic circuits, memory structures, passive components (such as resistors, capacitors, and inductors), and active components such as diodes, field-effect transistors (FETs), metal-oxide semiconductor field effect transistors (MOSFETs), complementary metal-oxide semiconductor (CMOS) transistors, bipolar transistors, high voltage transistors, high frequency transistors, fin-like FETs (FinFETs), other three-dimensional (3D) FETs, and combinations thereof. The semiconductor device 200 may include a plurality of semiconductor devices (e.g., transistors), which may be interconnected.

Referring to FIGS. 1 and 2A, the method 100 includes operation 102, in which a material layer 210 is deposited on a substrate 202, in accordance with some embodiments. FIG. 2A is a cross-sectional view of the semiconductor device 200 after depositing the material layer 210 on the substrate 202, in accordance with some embodiments.

In some embodiments, the substrate 202 may be a bulk semiconductor substrate including one or more semiconductor materials. In some embodiments, the substrate 202 may include silicon, silicon germanium, carbon doped silicon (Si:C), silicon germanium carbide, or other suitable semiconductor materials. In some embodiments, the substrate 202 is composed entirely of silicon.

In some embodiments, the substrate 202 may include one or more epitaxial layers formed on a top surface of a bulk semiconductor substrate. In some embodiments, the one or more epitaxial layers introduce strains in the substrate 202 for performance enhancement. For example, the epitaxial layer includes a semiconductor material different from that of the bulk semiconductor substrate, such as a layer of silicon germanium overlying bulk silicon or a layer of silicon overlying bulk silicon geranium. In some embodiments, the epitaxial layer(s) incorporated in the substrate 202 are formed by selective epitaxial growth, such as, for example, metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), or combinations thereof.

In some embodiments, the substrate 202 may be a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or other suitable technique, such as wafer bonding and grinding.

In some embodiments, the substrate 202 may also include a dielectric substrate such as silicon oxide, silicon nitride, silicon oxynitride, a low-k dielectric, silicon carbide, and/or other suitable layers.

In some embodiments, the substrate 202 may also include various p-type doped regions and/or n-type doped regions, implemented by a process such as ion implantation and/or diffusion. Those doped regions include n-well, p-well, lightly doped region (LDD) and various channel doping profiles configured to form various IC devices, such as a COMOS transistor, imaging sensor, and/or light emitting diode (LED). The substrate 202 may further include other functional features such as a resistor and/or a capacitor formed in and/or on the substrate 202.

In some embodiments, the substrate 202 may also include various isolation features. The isolation features separate various device regions in the substrate 202. The isolation features include different structures formed by using different processing technologies. For example, the isolation features may include shallow trench isolation (STI) features. The formation of an STI may include etching a trench in the substrate 202 and filling in the trench with insulator materials such as silicon oxide, silicon nitride, and/or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

In some embodiments, the substrate 202 may also include gate stacks formed by dielectric layers and electrode layers. The dielectric layers may include an interfacial layer and a high-k dielectric layer deposited by suitable techniques, such as chemical vapor deposition (CVD), atomic layer deposition (ALD), physical vapor deposition (PVD), thermal oxidation, combinations thereof, and/or other suitable techniques. The interfacial layer may include silicon dioxide and the high-k dielectric layer may include LaO, AlO, ZrO, TiO, Ta₂O₅, Y₂O₃, SrTiO₃, BaTiO₃, BaZrO, HfZrO, HfLaO, HfSiO, LaSiO, AlSiO, HfTaO, HfTiO, (Ba,Sr)TiO₃(BST), Al₂O₃, Si₃N₄, SiON, and/or other suitable materials. The electrode layer may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide. The electrode layer may include Ti, Ag, Al, TiAlN, TaC, TaCN, TaSiN, Mn, Zr, TiN, TaN, Ru, Mo, Al, WN, Cu, W, any suitable materials, and/or a combination thereof.

In some embodiments, the substrate 202 may also include a plurality of inter-level dielectric (ILD) layers and conductive features integrated to form an interconnect structure configured to couple the various p-type and n-type doped regions and the other functional features (such as gate electrodes), resulting in a functional integrated circuit. In one example, the substrate 202 may include a portion of the interconnect structure and the interconnect structure may include a multi-layer interconnect (MLI) structure and an ILD layer integrated with a MLI structure, providing an electrical routing to couple various devices in the substrate 202 to the input/output power and signals. The interconnect structure includes various metal lines, contacts and via features (or via plugs). The metal lines provide horizontal electrical routing. The contacts provide vertical connection between silicon substrate and metal lines while via features provide vertical connection between metal lines in different metal layers.

The material layer 210 is disposed on the substrate 202. The material layer 210 is a layer to be processed by the method 100, such as to be pattered or to be implanted. In some embodiments, the material layer 210 is a hardmask layer to be patterned. In some embodiments, the material layer 210 includes a dielectric material such as silicon oxide, silicon nitride, or silicon oxynitride. In some other embodiments, the material layer 210 includes a metal oxide such as titanium oxide or a metal nitride such as titanium nitride. In some embodiments, the material layer 210 also serves as an anti-reflection coating (ARC) layer whose composition is chosen to minimize reflectivity of radiation implemented during exposure of the photoresist layer 220. For example, in some embodiments, the material layer 210 includes silicon oxide, silicon oxygen carbide, or plasma enhanced chemical vapor deposited silicon oxide. The material layer 210 may be formed by any suitable process including chemical vapor deposition (CVD), physical vapor deposition (PVD), plasma enhanced chemical vapor deposition (PECVD), atomic layer deposition (ALD), or spin coating, and may be formed to any suitable thickness.

Referring to FIGS. 1 and 2B, the method 100 proceeds to operation 104, in which a photoresist composition is coated on the material layer 210 to form a photoresist layer 220, in accordance with some embodiments. FIG. 2B is a cross-sectional view of the semiconductor device 200 after forming the photoresist layer 220 on the material layer 210, in accordance with some embodiments.

The photoresist layer 220 is a photosensitive layer that is patterntable by exposure to actinic radiation. In some embodiments, the photoresist layer 220 is sensitive to ultraviolet radiation. In some embodiments, the ultraviolet radiation is deep ultraviolet (DUV) radiation. In some embodiments, the ultraviolet radiation is extreme ultraviolet (EUV) radiation. In some embodiments, the radiation is an electron beam.

In some embodiments, the photoresist composition includes a thiol-containing polymer.

In some embodiments, the thiol-containing polymer is a copolymer comprising two or more hydrocarbon monomeric units that forms a backbone of the polymer. The monomeric units may be derived from acrylic esters, methacrylic esters, crotonic esters, vinyl esters, maleic diesters, fumaric diesters, itaconic diesters, (meth)acrylonitrile, (meth)acrylamides, styrenes, hydroxystyrenes, vinyl ethers, novolacs, combinations of these, or the like.

In some embodiments, the thiol-containing polymer has a thiol group attached to the polymer backbone and the thiol group is one or more of a C6-C20 thiol-benzyl group, a C1-C20 thiol-alkyl group, a C3-C20 thiol-cycloalkyl group, a C1-C20 thiol-hydroxylalkyl group, a C2-C20 thiol-alkoxy group, a C3-C20 thiol-alkoxy alkyl group, a C1-C20 thiol-acetyl group, a C2-C20 thiol-acetylalkyl group, a C1-C20 thiol-carboxyl group, a C2-C20 thiol-alkyl carboxyl group, a C4-C20 thiol-cycloalkyl carboxyl group, a C3-C20 saturated or unsaturated thiol-hydrocarbon ring, or a C3-C20 thiol-heterocyclic group. In some embodiments, the thiol groups are substituted with one, two, three, or more thiol atoms.

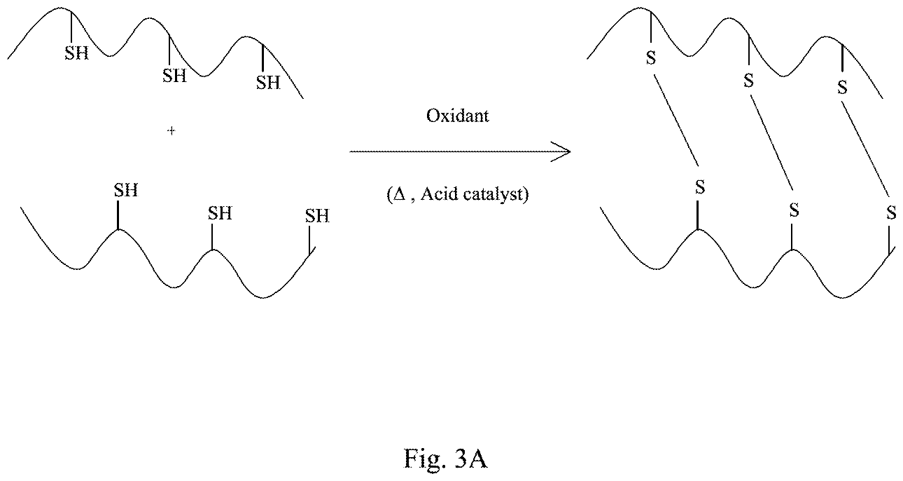

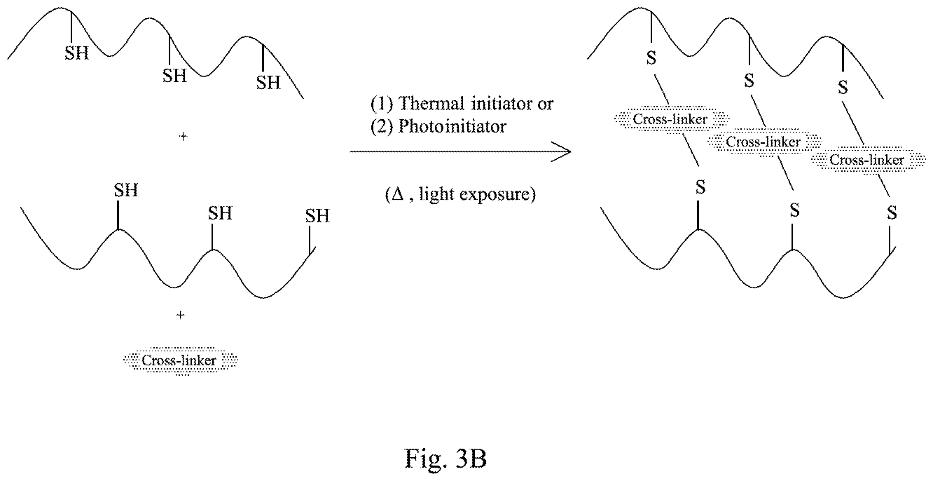

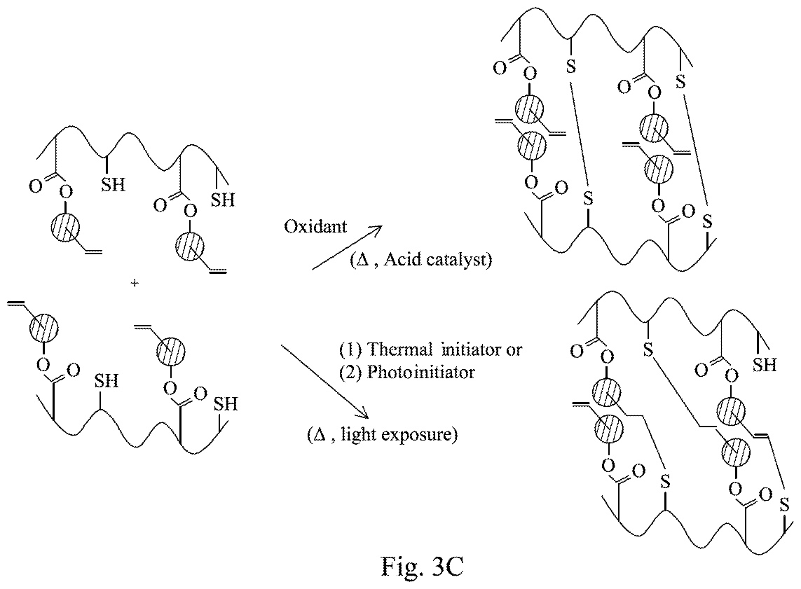

The thiol group in the thiol-containing polymer can be crosslinked by any suitable methods. In some embodiments, the thiol-containing polymer may be crosslinked by the formation of interchain disulfide bonds between polymer chains via an acid catalyzed oxidation of thiol groups in the presence of an oxidation agent (FIG. 3A). In some embodiments, the thiol-containing polymer may be crosslinked using a crosslinker comprising crosslinking groups that react with the thiol groups via photo- or thermal initiated “click” reactions like thiol-ene or thiol-yne reactions to create bridges between polymer chains (FIG. 3B). In some embodiments, the thiol-containing polymer also contains a radical-active functional group such as an alkene or alkyne group, so that the thiol-containing polymer may be crosslinked via the oxidative disulfide formation or via the thiol-ene or thiol-yne “click” reactions (FIG. 3C). Crosslinking increases the molecular weight, consequently raising the glass transition temperature Tg of the crosslinked thiol-containing polymer. Such increase in the glass transition temperature helps to restrict the acid diffusion length, which leads to improved patterning resolution and reduced line width roughness (LWR).

In some embodiments, the thiol-containing polymer has the following structure (I):

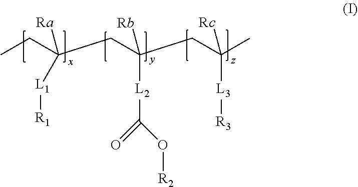

wherein:
   L₁, L₂ and L₃ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers;
   R₁ is, at each occurrence, independently a C5-C20 aryl group, wherein the aryl is unsubstituted or substituted with a halogen, a carbonyl group, a hydroxyl group or Rₛ₁;
   R₂ is, at each occurrence, independently an acid liable group, wherein the acid liable group is unsubstituted or substituted with Rₛ₁;
   R₃ is, at each occurrence, independently a C1-C20 alkyl, C1-C20 heteroalkyl, C4-C20 cycloalkyl, C2-C30 heterocycloalkyl, C5-C20 aryl, C5-C20 heteroaryl or Rₛ₁ group;
   Rₛ₁ is SH, a C1-C20 thioalkyl, C3-C20 thiocycloalkyl, C1-C20 thiohydroxylalkyl, C2-C20 thioalkoxy, C3-C20 thioalkoxyl alkyl, C1-C20 thioacetyl, C2-C20 thioacetylalkyl, thiocarboxyl, C2-C20 thioalkyl carboxyl, C4-C20 thiocycloalkyl carboxyl, C3-C20 thiocarbocyclic or C3-C20 heterothiocyclic group;
   Rₐ, R_{b} and R_{c} are, at each occurrence, independently H or a C1-C3 alkyl group; and
   0<x≤1, 0<y≤1, and 0≤z≤1, provided that one or more of R₁, R₂ and R₃ comprise Rₛ₁ such that the compound of structure (I) comprises at least one Rₛ₁.

In some embodiments, L₁, L₂ and L₃ are each a direct bond.

In some embodiments, L₁ is a direct bond, L₂ is phenylene, and L₃ is carbonyloxy (—COO—).

In some embodiments, L₁ and L₃ are each carbonyloxy (—COO—), and L₂ is a direct bond.

R₁ is a sensitizer group adapted to absorb actinic radiation. In some embodiments, R₁ is, at each occurrence, independently a unsubstituted or Rₛ₁ substituted hydroxyphenyl, unsubstituted or Rₛ₁ substituted hydroxynaphthalenyl, unsubstituted or Rₛ₁ substituted hydroxyanthracenyl, unsubstituted or Rₛ₁ substituted phenyl, unsubstituted or Rₛ₁ substituted naphatahlenyl or unsubstituted or Rₛ₁ substituted anthracenyl group.

In some embodiments, R₁ is unsubstituted or Rₛ₁ substituted hydroxyphenyl.

In some embodiments, R₁ is unsubstituted or Rₛ₁ substituted phenyl.

The acid labile group (ALG) is a group that will decompose be cleaved from the thiol-containing polymer by a reaction with an acid. In some embodiments, R₂ is, at each occurrence, independently a unsubstituted or Rₛ₁ substituted C4-C12 alkyl, unsubstituted or Rₛ₁ substituted C4-C12 cycloalkyl, unsubstituted or Rₛ₁ substituted C4-C12 hydroxyalkyl, unsubstituted or Rₛ₁ substituted C4-C12 alkoxy, unsubstituted or Rₛ₁ substituted C4-C12 alkoxy alkyl group, or a unsubstituted or Rₛ₁ substituted three-dimensional (3D) ring structure.

In some embodiments, R₂ is a tertiary alkyl group, such as a t-butyl or t-pentyl group, wherein the t-butyl or t-pentyl is unsubstituted or substituted with Rₛ₁.

In some embodiments, R₂ is a cycloalkyl group, such as a cyclopentyl, cyclohexyl methyl, or cyclohexyl ethyl group, wherein the cyclopentyl, cyclohexyl methyl, or cyclohexyl ethyl is unsubstituted or substituted with Rₛ₁.

In some embodiments, the 3D ring structure is an adamantyl, cedryl, norbornyl, or tricyclodecanyl structure, wherein the adamantyl, cedryl, norbornyl, or tricyclodecanyl structure is unsubstituted or substituted with Rₛ₁.

In some embodiments, R₂ has one of the following structures:

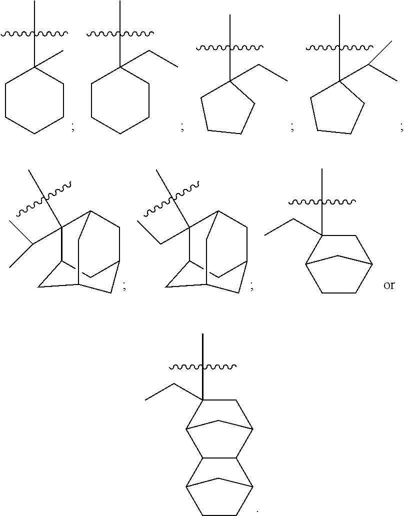

In some embodiments, R₃ is a lactone group adapted to assist in reducing the amount of line edge roughness

In some embodiments, R₃ is a C1-C12 alkyl or C4-C12 cycloalkyl group.

In some embodiments, R₃ is methyl.

In some embodiments, R₃ is Rₛ₁.

In some embodiments, Rₛ₁ is SH.

In some embodiments, at least one of Rₐ, R_{b} and R_{c} is H. In some embodiments, each of Rₐ, R_{b} and R_{c} is H.

In some embodiments, at least one of Rₐ, R_{b} and R_{c} is methyl. In some embodiments, each of Rₐ, R_{b} and R_{c} is methyl.

In some embodiments, 0.1≤x/(x+y+z)≤0.5, 0.2≤y/(x+y+z)≤0.7, and 0.05≤z/(x+y+z)≤0.5.

In some embodiments, the polymer of structure (I) has a weight average molecular weight ranging from 0.5 to 1,000 kDa. In some embodiments, the polymer has a weight molecular weight ranging from 2 to 250 kDa.

In some more specific embodiments, L₁, L₂, and L₃ are independently a direct bond, R₁ is a Rₛ₁ substituted hydroxyphenyl group, and R₃ is methyl. In some related embodiments, the thiol-containing polymer of structure (I) has the following structure (Ia):

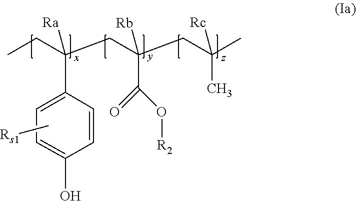

wherein:
   R₂ is, at each occurrence, independently C4-C12 alkyl, C4-C12 cycloalkyl, C4-C12 hydroxyalkyl, C4-C12 alkoxy, C4-C12 alkoxy alkyl or a three-dimensional (3D) ring structure.

In some more specific embodiments, Rₛ₁ is SH, and the thiol-containing polymer of structure (Ia) has the following structure (Ia-1)

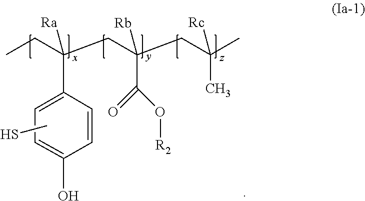

In some more specific embodiments, L₁, L₂, and L₃ are independently a direct bond, R₁ is hydroxyphenyl, R₂ is a Rₛ₁ substituted acid labile group, and R₃ is methyl. In some related embodiments, the thiol-containing polymer of structure (I) has the following structure (Ib):

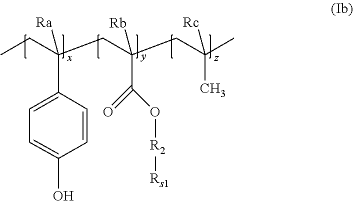

wherein:
   R₂ is, at each occurrence, independently C4-C12 alkyl, C4-C12 cycloalkyl, C4-C12 hydroxyalkyl, C4-C12 alkoxy, C4-C12 alkoxy alkyl or a three-dimensional (3D) ring structure.

In some more specific embodiments, Rₛ₁ is SH, and the thiol-containing polymer of structure (Ib) has the following structure (Ib-1):

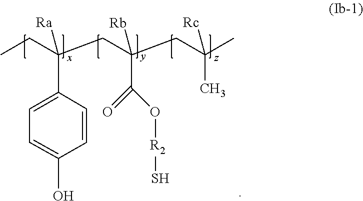

In some more specific embodiments, L₁, L₂, and L₃ are independently a direct bond, R₁ is hydroxyphenyl, and R₃ is Rₛ₁. In some related embodiments, the thiol-containing polymer has the following structure (Ic):

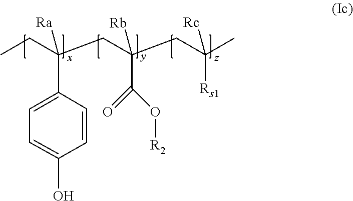

wherein:
   R₂ is, at each occurrence, independently C4-C12 alkyl, C4-C12 cycloalkyl, C4-C12 hydroxyalkyl, C4-C12 alkoxy, C4-C12 alkoxy alkyl or a three-dimensional (3D) ring structure.

In some more specific embodiments, Rₛ₁ is SH, and the thiol-containing polymer of structure (Ic) has the following structure (Ic-1):

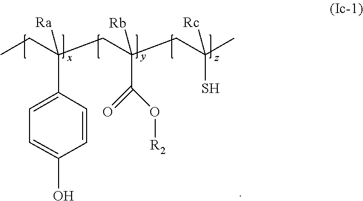

In some more specific embodiments, L₁, L₂, and L₃ are independently a direct bond, R₁ is a Rₛ₁ substituted phenyl group, and R₃ is methyl. In some related embodiments, the thiol-containing polymer of structure (I) has the following structure (Id):

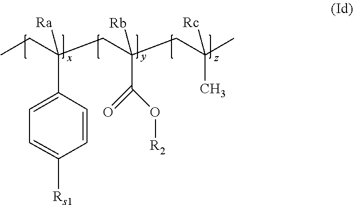

wherein:
   R₂ is, at each occurrence, independently C4-C12 alkyl, C4-C12 cycloalkyl, C4-C12 hydroxyalkyl, C4-C12 alkoxy, C4-C12 alkoxy alkyl or a three-dimensional (3D) ring structure.

In some more specific embodiments, Rₛ₁ is SH, and the thiol-containing polymer of structure (Id) has the following structure (Id-1)

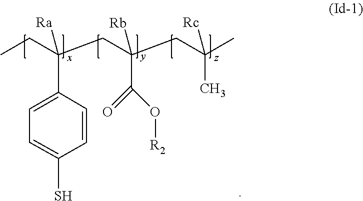

In some embodiments, the thiol-containing polymer has the following structure (II):

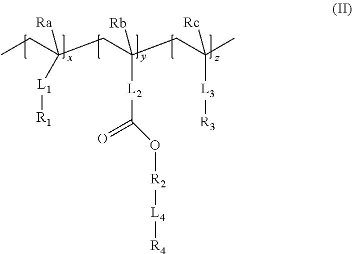

wherein:
   L₁, L₂, L₃ and L₄ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers;
   R₁ is, at each occurrence, independently a C5-C20 aryl group, wherein the aryl is unsubstituted or substituted with a halogen, a carbonyl group, a hydroxyl group or Rₛ₁;
   R₂ is, at each occurrence, independently a divalent acid liable group;
   R₃ is, at each occurrence, independently a C1-C20 alkyl, C1-C20 heteroalkyl, C4-C20 cycloalkyl, C2-C30 heterocycloalkyl, C5-C20 aryl, C5-C20 heteroaryl or Rₛ₁ group;
   R₄ is, at each occurrence, independently a radical-active functional group;
   Rₛ₁ is SH, a C1-C20 thioalkyl, C3-C20 thiocycloalkyl, C1-C20 thiohydroxylalkyl, C2-C20 thioalkoxy, C3-C20 thioalkoxyl alkyl, C1-C20 thioacetyl, C2-C20 thioacetylalkyl, thiocarboxyl, C2-C20 thioalkyl carboxyl, C4-C20 thiocycloalkyl carboxyl, C3-C20 thiocarbocyclic or C3-C30 heterothiocyclic group;
   Rₐ, R_{b} and R_{c} are, at each occurrence, independently H or a C1-C3 alkyl group; and
   0<x≤1, 0<y≤1, and 0≤z≤1, provided that R₁, R₃ or both comprises Rₛ₁ such that the compound of structure (II) comprises at least one Rₛ₁.

In some embodiments, L₁, L₂, L₃ and L₄ are each a direct bond.

In some embodiments, L₁, L₂ and L₃ are each a direct bond, and L⁴ is oxy (—O—), carbonyl (—CO—), carbonyloxy (—COO—) or methylene (—CH₂—).

In some embodiments, L₁ and L₄ are each a direct bond, L₂ in phenylene, L³ is carbonyloxy (—COO—).

In some embodiments, L₁, L₃, and L₄ are each carbonyloxy (—COO—), and L₂ is a direct bond.

R₁ is a sensitizer group adapted to absorb the actinic radiation. In some embodiments, R₁ is, at each occurrence, independently a unsubstituted or Rₛ₁ substituted hydroxyphenyl, unsubstituted or Rₛ₁ substituted hydroxynaphthalenyl, unsubstituted or Rₛ₁ substituted hydroxyanthracenyl, unsubstituted or Rₛ₁ substituted phenyl, unsubstituted or Rₛ₁ substituted naphatahlenyl or unsubstituted or Rₛ₁ substituted anthracenyl group.

In some embodiments, R₁ is unsubstituted or Rₛ₁ substituted hydroxyphenyl.

The acid labile group (ALG) is a group that will decompose be cleaved from the thiol-containing polymer by a reaction with an acid. In some embodiments, R₂ is, at each occurrence, independently a unsubstituted or Rₛ₁ substituted C4-C12 alkyl, unsubstituted or Rₛ₁ substituted C4-C12 cycloalkyl, unsubstituted or Rₛ₁ substituted C4-C12 hydroxyalkyl, unsubstituted or Rₛ₁ substituted C4-C12 alkoxy or unsubstituted or Rₛ₁ substituted C4-C12 alkoxy alkyl divalent group, or a unsubstituted or Rₛ₁ substituted divalent three-dimensional (3D) ring structure.

In some embodiments, R₂ is a tertiary alkyl divalent group, such as a t-butyl or t-pentyl divalent group, wherein the divalent t-butyl or t-pentyl is unsubstituted or substituted with Rₛ₁.

In some embodiments, R₂ is a cycloalkyl divalent group, such as a cyclopentyl, cyclohexyl methyl, or cyclohexyl ethyl divalent group, wherein the divalent cyclopentyl, cyclohexyl methyl, or cyclohexyl ethyl is unsubstituted or substituted with Rₛ₁.

In some embodiments, the divalent 3D ring structure is a divalent adamantyl, cedryl, norbornyl, or tricyclodecanyl structure, wherein the divalent adamantyl, cedryl, norbornyl, or tricyclodecanyl structure is unsubstituted or substituted with Rₛ₁.

In some embodiments, R₂ has one of the following structures (the “ [symbol] ” indicates a linkage to the polymer backbone):

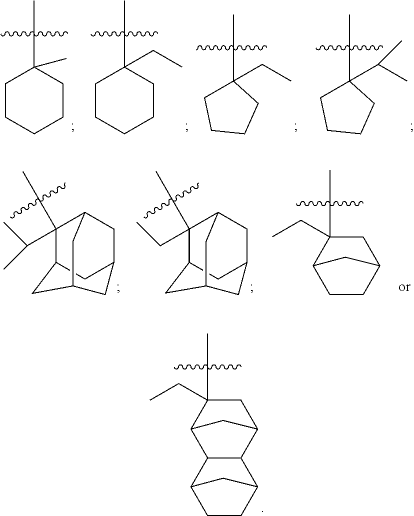

In some embodiments, R₃ is a lactone group adapted to assist in reducing the amount of line edge roughness

In some embodiments, R₃ is a C1-C12 alkyl or C4-C12 cycloalkyl group.

In some embodiments, R₃ is methyl.

In some embodiments, R₃ is Rₛ₁.

The radical-active functional group is a group that is activated by a free radical and undergoes a thiol-ene/yne reaction with a thiol group. In some embodiments, R₄ is an alkene or alkyne group.

In some embodiments, Rₛ₁ is SH.

In some embodiments, at least one of Rₐ, R_{b} and R_{c} is H. In some embodiments, each of Rₐ, R_{b} and R_{c} is H.

In some embodiments, at least one of Rₐ, R_{b} and R_{c} is methyl. In some embodiments, each of Rₐ, R_{b} and R_{c} is methyl.

In some embodiments, 0.1≤x/(x+y+z)≤0.5, 0.2≤y/(x+y+z)≤0.7, and 0.05≤z/(x+y+z)≤0.5.

In some embodiments, the polymer of structure (II) has a weight average molecular weight ranging from 0.5 to 1,000 kDa. In some embodiments, the polymer has a weight molecular weight ranging from 2 to 250 kDa.

In some more specific embodiments, L₁, L₂, and L₃ are independently a direct bond, R₁ is a Rₛ₁ substituted hydroxyphenyl group, R₃ is methyl, and R₄ is alkene. In some related embodiments, the thiol-containing polymer of structure (II) has the following structure (IIa):

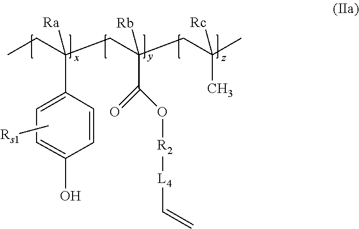

wherein:
   R₂ is, at each occurrence, independently a C4-C12 alkyl, C4-C12 cycloalkyl, C4-C12 hydroxyalkyl, C4-C12 alkoxy, C4-C12 alkoxy alkyl divalent group or a divalent three-dimensional (3D) ring structure.

In some more specific embodiments, Rₛ₁ is SH, and the thiol-containing polymer of structure (IIa) has the following structure (Ia-1):

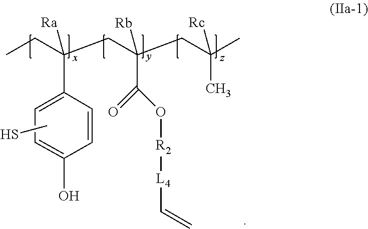

In some more specific embodiments, L₁, L₂, and L₃ are independently a direct bond, R₁ is hydroxyphenyl, and R₃ is Rs1. In some related embodiments, the thiol-containing polymer of structure (II) has the following structure (IIb):

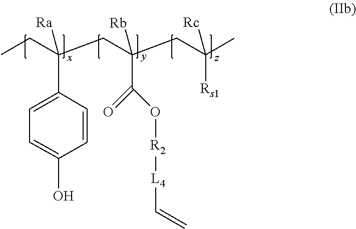

wherein:
   R₂ is, at each occurrence, independently a C4-C12 alkyl, C4-C12 cycloalkyl, C4-C12 hydroxyalkyl, C4-C12 alkoxy or C4-C12 alkoxy alkyl divalent group or a divalent three-dimensional (3D) ring structure.

In some more specific embodiments, Rₛ₁ is SH, and the thiol-containing polymer of structure (IIb) has the following structure (IIb-1)

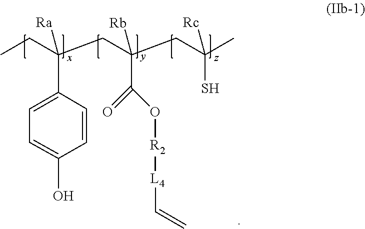

In some more specific embodiments, L₁, L₂, and L₃ are independently a direct bond, R₁ is a Rs1 substituted phenyl group, and R₃ is methyl. In some related embodiments, the thiol-containing polymer of structure (II) has the following structure (IIc):

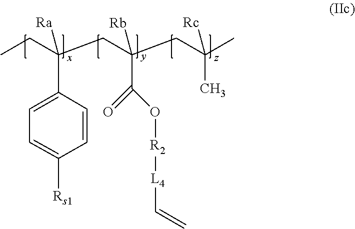

wherein:
   R₂ is, at each occurrence, independently a C4-C12 alkyl, C4-C12 cycloalkyl, C4-C12 hydroxyalkyl, C4-C12 alkoxy or C4-C12 alkoxy alkyl divalent group or a divalent three-dimensional (3D) ring structure.

In some more specific embodiments, Rₛ₁ is SH, and the thiol-containing polymer of structure (IIc) has the following structure (IIc-1)

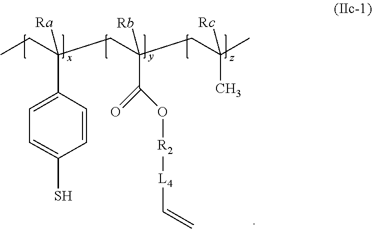

In some specific embodiments, the thiol-containing polymer of structure (I) is a compound selected from Table 1.

TABLE 1
Exemplary Thio-Containing Polymer of Structure (I) or (II)

| No. | Structure |
|---|---|
| I-1 | 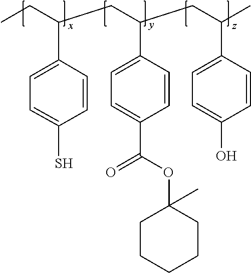 |
| I-2 | 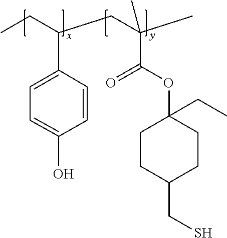 |
| I-3 | 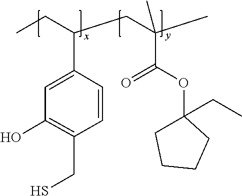 |
| I-4 | 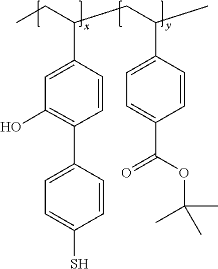 |
| II-1 | 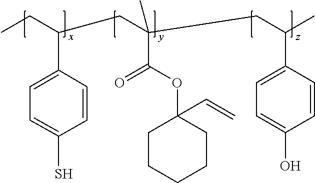 |
| II-2 | 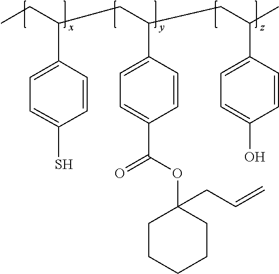 |

In some embodiments, an oxidation agent and an acid catalyst may be added to the photoresist composition. The oxidation agent and the acid catalyst cause the oxidation of thiol groups in the polymer of structure (I) or (II), forming disulfide bridges between polymer chains to crosslink the polymer (FIGS. 3A and 3C). The oxidative disulfide bond formation increases the glass transition temperature Tg of the resulting crosslinked polymer, which helps to improve the patterning resolution and LWR. Suitable oxidation agent that can be used include, but not limited to, oxygen, H₂O₂, LiBrO₃, NaBrO₃, KBrO₃, O₃, I₂, or combinations thereof. The acid catalyst is selected to have a pKa greater than 1. If the acidity of the acid catalyst is too strong, the acid labile group R₂ in the polymer may decompose, which leads to photoresist malfunction. Suitable acid catalysts that can be used include, but not limited to, acetic acid (CH₃COOH), hydrochloric acid (HCl), carbonic acid (H₂CO₃), or combinations thereof.

Alternatively, instead of or in addition to the oxidation agent and an acid catalyst being added to the photoresist composition, a crosslinker is added in some embodiments. The crosslinker contains crosslinking groups that can react with thiol groups of the thiol-containing polymer of structure (I) to bond two polymer chains together (FIG. 3B). The bonding increases the glass transition temperature Tg of the resulting crosslinked polymer, which helps to improve the patterning resolution and LWR. In some embodiments, the crosslinker comprises two to six crosslinking groups including, for example, epoxy, hydroxy, melamine, alkene, alkyne, or vinyl ether.

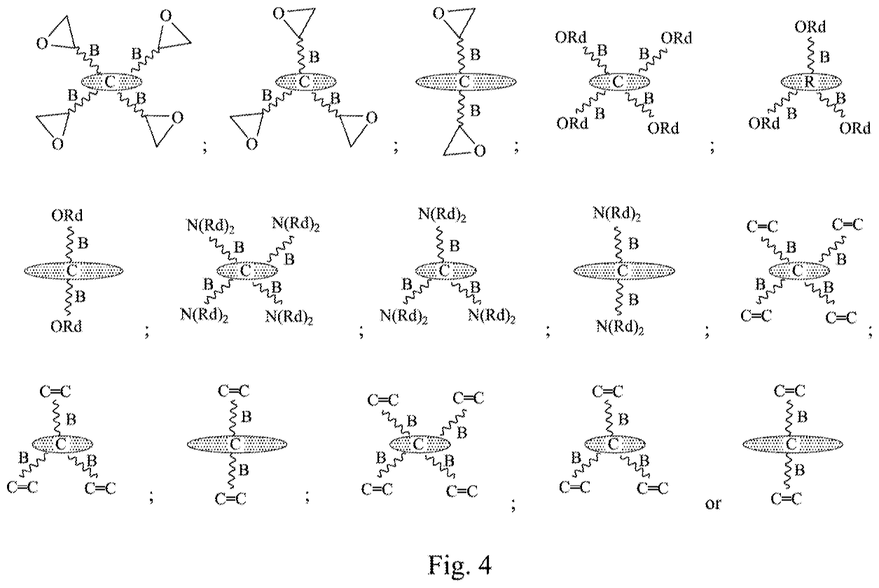

FIG. 4 illustrate examples of the crosslinkers that can be used in the present disclosure. A crosslinker may include two or more crosslinking groups that provide crosslinking sites. In some embodiments, as shown in FIG. 4, a crosslinker includes a core group C and two or more crosslinking groups covalently bonded to the core group C via linkers B. The linker length is controlled to such that B linker is rotatable for achieving high crosslinking reaction efficiency in the exposure areas. The high crosslinking efficiency between the thiol groups in the thiol-containing polymer (I) and the crosslinker allows for using lower EUV exposure doses for lithography patterning.

In some embodiments, the core group C may include a divalent or multivalent C1-C20 alkyl group, a C3-C20 divalent or multivalent cycloalkyl group, a divalent or multivalent C2-C20 heteroalkyl group, a C3-C20 divalent or multivalent cycloheteroalkyl group, a C5-C20 divalent or multivalent aryl group, or a C3-C20 divalent or multivalent heteroaryl group. The linker B that couples the core group C to the crosslinking group may include a C2-C20 alkylene group, a C3-C20 cycloalkylene group, a C2-C20 heteroalkylene, a C2-C20 hydroxyalkylene group, a C2-C20 acetylene group, a C2-C20 acetylalkylene group, a C2-C20 alkylene carboxyl group, a C4-C20 cycloalkylene carboxyl group, a C3-C20 saturated or unsaturated hydrocarbon ring, or a C2-C20 heteroalkylene group. In some embodiments, the crosslinking group may include an epoxy, ORd, O(Rd)₂, C═C, or C—C, wherein Rd is H, a C1-C8 alkyl group, a C3-C8 cycloalkyl group, a C1-C8 hydroxyalkyl group, a C1-C8 alkoxy group, a C2-C8 alkoxy alkyl group, a C1-C8 acetyl group, C2-C8 acetylalkyl group, a C2-C8 alkyl carboxyl group, a C4-C8 cycloalkyl carboxyl group, a C3-C8 saturated or unsaturated hydrocarbon ring, or a C3-C8 heterocyclic group.

In some embodiments, the core group C has one of the following structure:

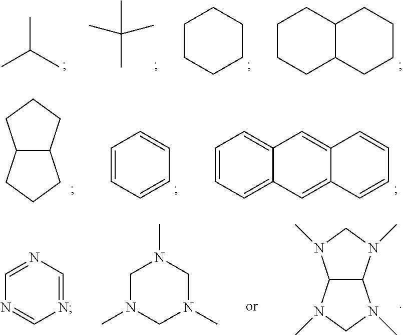

In some embodiments, the linker A is O, alkylene oxide or polyethylene oxide.

In some embodiments, the crosslinker has one of the following structures:

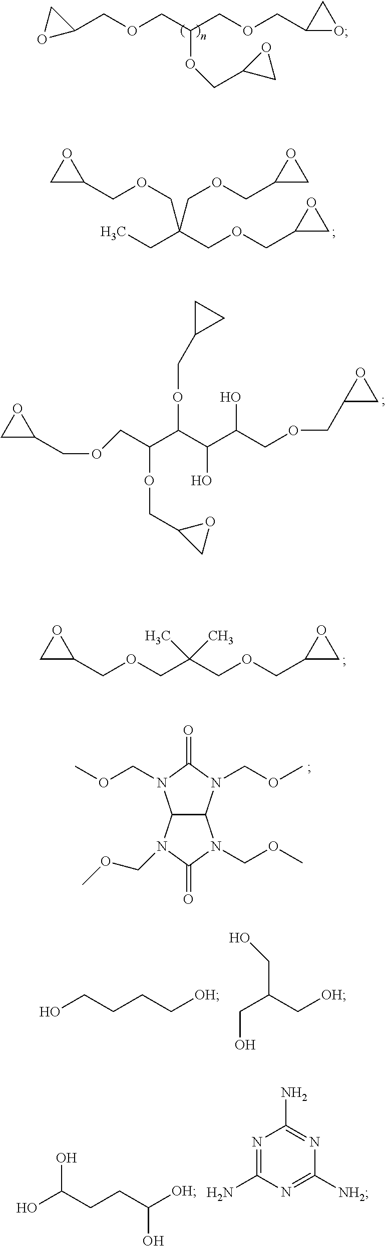

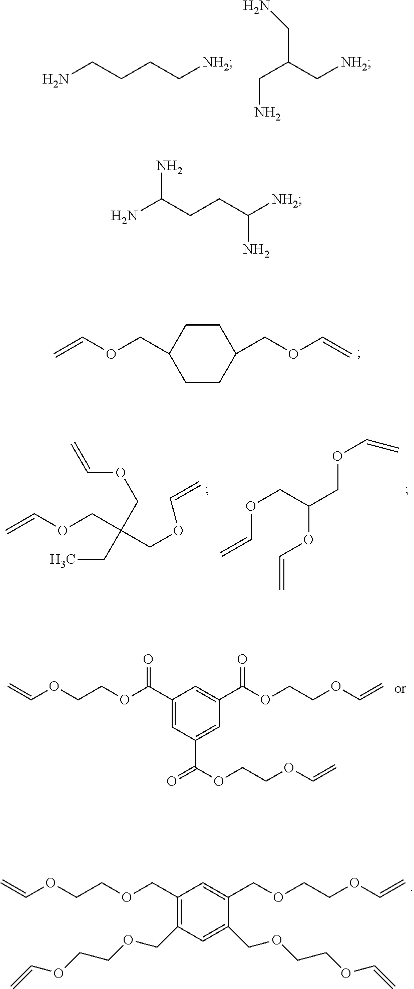

In some embodiments, the concentration of the crosslinker in the photoresist composition ranges from about 0.1 wt % to about 50 wt % based on the total weight of the polymer taken as 100%. In some other embodiments, the concentration of the crosslinker in the photoresist composition ranges from about 5 wt % to about 20 wt % based on the total weight of crosslinker and the polymer. Photoresist compositions having less than about 0.1 wt % of the crosslinker may undergo insufficient crosslinking during photoresist patterning. Photoresist compositions having more than 50 wt % of the crosslinker may result in reduced photoresist pattern resolution or increased line width roughness (LWR).

In instances where the crosslinking is achieved by the reaction between crosslinking groups attached to the polymer backbone (e.g., thiol-thiol or thiol-alkene groups), the addition of a crosslinker is not necessary.

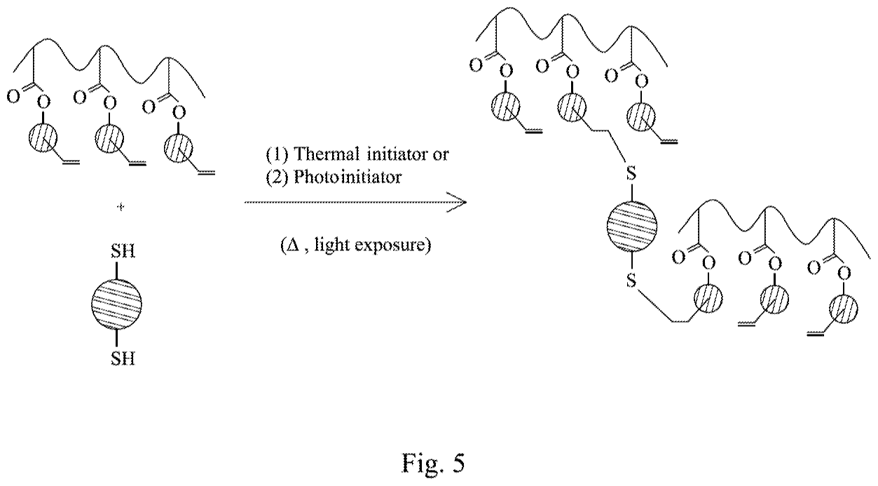

In some embodiments, instead of using a thiol-containing polymer, the photoresist composition includes a polymer comprising crosslinkable alkene or alkyne groups and a thiol-containing crosslinker to crosslink the polymer via a “click” reaction, such as thiol-ene/yne reaction, upon UV radiation or heating as shown in FIG. 5.

In some embodiments, the non-thiol containing polymer has the following structure (III):

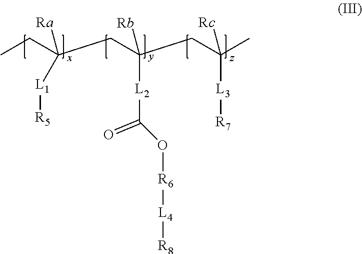

wherein:
   L₁, L₂, L₃ and L₄ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers;
   R₅ is, at each occurrence, independently a C5-C20 aryl group, wherein the aryl is unsubstituted or substituted with a halogen, a carbonyl group or a hydroxyl group;
   R₆ is, at each occurrence, independently a divalent acid liable group;
   R₇ is, at each occurrence, independently a C1-C20 alkyl, C1-C20 heteroalkyl, C4-C20 cycloalkyl, C2-C30 heterocycloalkyl, C5-C20 aryl or C5-C20 heteroaryl group;
   R₈ is, at each occurrence, independently a radical-active functional group;
   Rₐ, R_{b} and R_{c} are, at each occurrence, independently H or a C1-C3 alkyl group; and
   0<x≤1, 0<y≤1, and 0≤z≤1.

In some embodiments, L₁, L₂, L₃ and L₄ are each a direct bond.

In some embodiments, L₁, L₂ and L₃ are each a direct bond, and L⁴ is oxy (—O—), carbonyl (—CO—), carbonyloxy (—COO—) or methylene (—CH₂—).

In some embodiments, L₁ and L₄ are each a direct bond, L₂ in phenylene, L³ is carbonyloxy (—COO—).

In some embodiments, L₁, L₃, and L₄ are each carbonyloxy (—COO—), and L₂ is a direct bond.

R₅ is a sensitizer group adapted to absorb the actinic radiation. In some embodiments, R₅ is, at each occurrence, independently hydroxyphenyl, hydroxynaphthalenyl, hydroxyanthracenyl, phenyl, naphatahlenyl or anthracenyl.

In some embodiments, R₅ is hydroxyphenyl.

The acid labile group (ALG) is a group that will decompose be cleaved from the thiol-containing polymer by a reaction with an acid. In some embodiments, R₆ is, at each occurrence, independently a C4-C12 alkyl, C4-C12 cycloalkyl, C4-C12 hydroxyalkyl, C4-C12 alkoxy or C4-C12 alkoxy alkyl divalent group, or a divalent three-dimensional (3D) ring structure.

In some embodiments, R₆ is a tertiary alkyl divalent group, such as a t-butyl or t-pentyl divalent group.

In some embodiments, R₆ is a cycloalkyl divalent group, such as a cyclopentyl or cyclohexyl alkyl divalent group.

In some embodiments, the 3D ring structure is a divalent adamantyl, cedryl, norbornyl, or tricyclodecanyl structure.

In some embodiments, R₆ is a divalent moiety having one of the following structures (the “ [symbol] ” indicates a linkage to the polymer backbone):

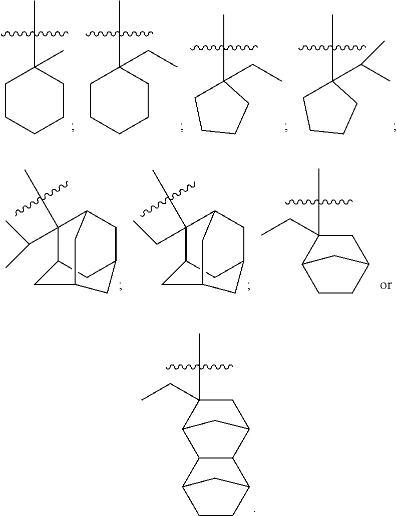

In some embodiments, R₇ is a lactone group adapted to assist in reducing the amount of line edge roughness

In some embodiments, R₇ is C1-C12 alkyl or C4-C12 cycloalkyl.

In some embodiments, R₇ is methyl.

The radical-active functional group is a group that is activated by a free radical and undergoes a thiol-ene/yne reaction with a thiol group. In some embodiments, R₈ is an alkene or alkyne group

In some embodiments, at least one of Rₐ, R_{b} and R_{c} is H. In some embodiments, each of Rₐ, R_{b} and R_{c} is H.

In some embodiments, at least one of Rₐ, R_{b} and R_{c} is methyl. In some embodiments, each of Rₐ, R_{b} and R_{c} is methyl.

In some embodiments, 0.1≤x/(x+y+z)≤0.5, 0.2≤y/(x+y+z)≤0.7, and 0.05≤z/(x+y+z)≤0.5.

In some embodiments, the polymer of structure (III) has a weight average molecular weight ranging from 0.5 to 1,000 kDa. In some embodiments, the polymer has a weight molecular weight ranging from 2 to 250 kDa.

In some more specific embodiments, L₁, L₂, and L₃ are independently a direct bond, R₅ is a hydroxyphenyl group, R₇ is methyl, and R₈ is alkene. In some related embodiments, the polymer of structure (III) has the following structure (IIIa):

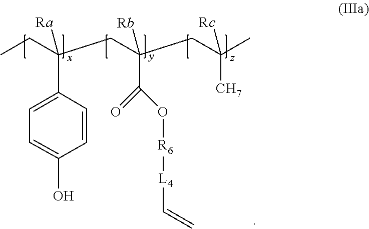

wherein each occurrence of L₄, R₂, Rₐ, R_{b}, and R_{c} are independently defined above for a polymer of structure (III).

In some specific embodiments, the thiol-containing polymer of structure (III) is a compound selected from Table 2.

TABLE 2
Exemplary Non-Thio-Containing Polymer of
Structure (III)

| No. | Structure |
|---|---|
| III-1 | 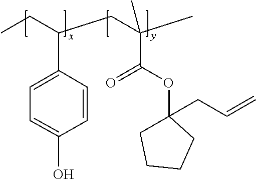 |
| III-2 | 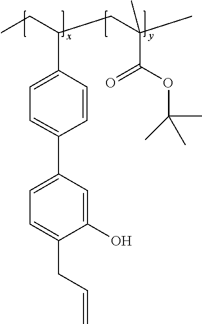 |

In some embodiments, the thiol-containing crosslinker is a polythiol having the following structure (IV):

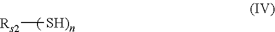

wherein:
   R₂ is a C1-C20 alkylene, C1-C20 alkylene carboxyl, C3-C20 cycloalkylene carboxyl, C3-C20 saturated or unsaturated carbocyclic or C3-C20 heterocyclic group; and
   n is an integer from 2 to 6

In some embodiments, n is 2, 3, 4, 5 or 6.

In some embodiments, the thiol-containing crosslinker comprises 1,2-ethanedithiol, 1,4-butanedithiol, 1,6-hexanedithiol, tetra(ethylene glycol) dithiol, ethane-1,1,2-trithiol, ethane-1,1,2,2-tetrathiol, ethylene glycol bis(3-mercaptopropionate) (EGBMP), dipentaerythritol hexakis(3-mercaptopropionate) (DPHMP), trimethylolpropane tris(3-mercaptopropionate) (TMPTMP), tris[2-(3-mercaptopropionyloxy)ethyl]isocyanurate and pentaerithritol tetrakis(3-mercaptopropionate) (PETMP).

In some embodiments, the photoresist composition includes one or more photoactive compounds (PACs). The PACs are photoacid generators (PAGs), photobase generators (PBG), photo decomposable bases (PDB), free radical generators (also referred to as photoinitiator), or the like. The PACs may be positive-acting or negative-acting. In some embodiments in which the PACs are photoacid generators (PAGs), the PAGs include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of photoacid generators include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl)sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like.

In some embodiments in which the PACs include free-radical generators, the free-radical generators including n-phenylglycine; aromatic ketones, including benzophenone, N,N′-tetramethyl-4,4′-diaminobenzophenone, N,N′-tetraethyl-4,4′-diaminobenzophenone, 4-methoxy-4′-dimethylaminobenzo-phenone, 3,3′-dimethyl-4-methoxybenzophenone, p,p′-bis(dimethylamino)benzo-phenone, p,p′-bis(diethylamino)-benzophenone; anthraquinone, 2-ethylanthraquinone; naphthaquinone; and phenanthraquinone; benzoins including benzoin, benzoinmethylether, benzoinisopropylether, benzoin-n-butylether, benzoin-phenylether, methylbenzoin and ethylbenzoin; benzyl derivatives, including dibenzyl, benzyldiphenyldisulfide, and benzyldimethylketal; acridine derivatives, including 9-phenylacridine, and 1,7-bis(9-acridinyl)heptane; thioxanthones, including 2-chlorothioxanthone, 2-methylthioxanthone, 2,4-diethylthioxanthone, 2,4-dimethylthioxanthone, and 2-isopropylthioxanthone; acetophenones, including 1,1-dichloroacetophenone, p-t-butyldichloro-acetophenone, 2,2-diethoxyacetophenone, 2,2-dimethoxy-2-phenylacetophenone, and 2,2-dichloro-4-phenoxyacetophenone; 2,4,5-triarylimidazole dimers, including 2-(o-chlorophenyl)-4,5-diphenylimidazole dimer, 2-(o-chlorophenyl)-4,5-di-(m-methoxyphenyl imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, 2-(2,4-dimethoxyphenyl)-4,5-diphenylimidazole dimer and 2-(p-methylmercaptophenyl)-4,5-diphenylimidazole dimmer; combinations of these, or the like.

In some embodiments, the PACs include photobase generators (PBG) and photo decomposable bases (PDB). In embodiments in which the PACs are photobase generators (PBG), the PBGs include quaternary ammonium dithiocarbamates, a aminoketones, oxime-urethane containing molecules such as dibenzophenoneoxime hexamethylene diurethan, ammonium tetraorganylborate salts, and N-(2-nitrobenzyloxycarbonyl) cyclic amines, combinations of these, or the like.

In some embodiments in which the PACs are photo decomposable bases (PDB), the PDBs include triphenylsulfonium hydroxide, triphenylsulfonium antimony hexafluoride, and triphenylsulfonium triflyl.

The photoresist composition may include PACs from about 0.1 wt % to 10 wt % based upon the total weight of the polymer taken as 100%. In some embodiments, the photoresist composition includes PACs from about 1 wt % to about 5 wt %. Photoresist compositions having less than about 0.01 wt % of PACs may results in low rates of crosslinking reaction. Photoresist compositions having more than 10 wt % of the PACs may result in reduced photoresist pattern resolution or increased line width roughness (LWR).

In some embodiments, instead of using a radical producing photoinitiator, the photoresist composition may alternatively or additionally include a thermal initiator capable of producing radicals for initiating crosslinking reaction under heat. In some embodiments, the thermal initiator comprises an organic peroxide. In some embodiments, the thermal initiator comprises an azo compound, an inorganic peroxide, an organic peroxide, or any combination thereof. In some embodiments, the thermal initiator is selected from the group consisting of tert-amyl peroxybenzoate, 4,4-azobis(4-cyanovaleric acid), 1,1′-azobis(cyclohexanecarbonitrile), 2,2′-azobisisobutyronitrile (AIBN), benzoyl peroxide, 2,2-bis(tert-butylperoxy)butane, 1,1-bis(tert-butylperoxy)cyclohexane, 2,5-bis(tert-butylperoxy_2,5-dimethylhexane, 2,5-bis(tert-butylperoxy)-2,5-dimethyl-3-hexyne, bis(1-(tert-butylperoxy)-3,3,5-trimethylcyclohexane, tert-butyl hydroxyperoxide, tert-butyl peracetate, tert-butyl peroxide, tert-butyl peroxybenzoate, tert-butylperoxy isopropyl carbonate, cumene hydroperoxide, cyclohexanone peroxide, dicumyl peroxide, lauroyl peroxide, 2,4-pentanedione peroxide, peracetic acid, potassium persulfate, a derivative thereof, and a combination thereof. In some embodiments, the thermal initiator comprises azobisisobutyronitrile, 2,2′-azodi(2-methylbutyronitrile), or a combination thereof.

In some embodiments, the photoresist composition comprises 0-10 wt %, based on the total weight of the polymer, of the thermal initiator. In some embodiments, the photoresist composition comprises 0.1-5 wt % of the thermal initiator.

The photoresist composition may also include a number of other optional additives. In some embodiments, a quencher is added to the photoresist composition to inhibit diffusion of the generated acids/bases/free radicals within the photoresist. The quencher improves the resist pattern configuration as well as the stability of the photoresist over time. In some embodiments, the quencher is an amine, such as a second lower aliphatic amine, a tertiary lower aliphatic amine, or the like. Specific examples of amines include trimethylamine, diethylamine, triethylamine, di-n-propylamine, tri-n-propylamine, tripentylamine, diethanolamine, and triethanolamine, alkanolamine, combinations thereof, or the like.

In some embodiments, an organic acid is used as the quencher. Specific embodiments of organic acids include malonic acid, citric acid, malic acid, succinic acid, benzoic acid, salicylic acid; phosphorous oxo acid and its derivatives, such as phosphoric acid and derivatives thereof such as its esters, phosphoric acid di-n-butyl ester and phosphoric acid diphenyl ester; phosphonic acid and derivatives thereof, including its ester, such as phosphonic acid dimethyl ester, phosphonic acid di-n-butyl ester, phenylphosphonic acid, phosphonic acid diphenyl ester, and phosphonic acid dibenzyl ester; and phosphinic acid and derivatives thereof, including its esters, such as phenylphosphinic acid.

In some embodiments, a stabilizer is added to the photoresist composition, which assists in preventing undesired diffusion of the acids generated during exposure of the photoresist. In some embodiments, the stabilizer includes nitrogenous compounds, including aliphatic primary, secondary, and tertiary amines; cyclic amines, including piperidines, pyrrolidines, morpholines; aromatic heterocycles, including pyridines, pyrimidines, purines; imines, including diazabicycloundecene, guanidines, imides, amides, or the like. Alternatively, ammonium salts are also be used for the stabilizer in some embodiments, including ammonium, primary, secondary, tertiary, and quaternary alkyl- and aryl-ammonium salts of alkoxides, including hydroxide, phenolates, carboxylates, aryl and alkyl sulfonates, sulfonamides, or the like. Other cationic nitrogenous compounds, including pyridinium salts and salts of other heterocyclic nitrogenous compounds with anions, such as alkoxides, including hydroxide, phenolates, carboxylates, aryl and alkyl sulfonates, sulfonamides, or the like, are used in some embodiments.

Another additive in some embodiments of the photoresist composition is a dissolution inhibitor to help control dissolution of the photoresist during development. In some embodiments, bile-salt esters may be used as the dissolution inhibitor. Specific examples of dissolution inhibitors in some embodiments include cholic acid, deoxycholic acid, lithocholic acid, t-butyl deoxycholate, t-butyl lithocholate, and t-butyl-3-acetyl lithocholate.

Another additive in some embodiments of the photoresist composition is a plasticizer. Plasticizers may be used to reduce delamination and cracking between the photoresist layer and the underlying layer (e.g., the material layer to be patterned). Plasticizers include monomeric, oligomeric, and polymeric plasticizers, such as oligo- and polyethyleneglycol ethers, cycloaliphatic esters, and non-acid reactive steroidaly-derived materials. Specific examples of materials used for the plasticizer in some embodiments include dioctyl phthalate, didodecyl phthalate, triethylene glycol dicaprylate, dimethyl glycol phthalate, tricresyl phosphate, dioctyl adipate, dibutyl sebacate, triacetyl glycerine, or the like.

A coloring agent is another additive included in some embodiments of the photoresist. The coloring agent observers examine the photoresist and find any defects that may need to be remedied prior to further processing. In some embodiments, the coloring agent is a triarylmethane dye or a fine particle organic pigment. Specific examples of materials in some embodiments include crystal violet, methyl violet, ethyl violet, oil blue, Victoria Pure Blue BOH, malachite green, diamond green, phthalocyanine pigments, azo pigments, carbon black, titanium oxide, brilliant green dye (C. I. 42020), Victoria Pure Blue FGA (Linebrow), Victoria BO (Linebrow) (C. I. 42595), Victoria Blue BO (C. I. 44045), rhodamine 6G (C. I. 45160), benzophenone compounds, such as 2,4-dihydroxybenzophenone and 2,2′,4,4′-tetrahydroxybenzophenone; salicylic acid compounds, such as phenyl salicylate and 4-t-butylphenyl salicylate; phenylacrylate compounds, such as ethyl-2-cyano-3,3-diphenylacrylate, and T-ethylhexyl-2-cyano-3,3-diphenylacrylate; benzotriazole compounds, such as 2-(2-hydroxy-5-methylphenyl)-2H-benzotriazole, and 2-(3-t-butyl-2-hydroxy-5-methylphenyl)-5-chloro-2H-benzotriazole; coumarin compounds, such as 4-methyl-7-diethylamino-1-benzopyran-2-one; thioxanthone compounds, such as diethylthioxanthone; stilbene compounds, naphthalic acid compounds, azo dyes, phthalocyanine blue, phthalocyanine green, iodine green, Victoria blue, naphthalene black, Photopia methyl violet, bromphenol blue and bromcresol green; laser dyes, such as Rhodamine G6, Coumarin 500, DCM (4-(dicyanomethylene)-2-methyl-6-(4-dimethylaminostyryl)-4H pyran)), Kiton Red 620, Pyrromethene 580, or the like. Additionally, one or more coloring agents may be used in combination to provide the desired coloring.

Adhesion additives may be added to some embodiments of the photoresist composition to promote adhesion between the photoresist layer 220 and the material layer 210. In some embodiments, the adhesion additives include a silane compound with at least one reactive substituent, such as a carboxyl group, a methacryloyl group, an isocyanate group, or an epoxy group. Specific examples of the adhesion components include trimethoxysilyl benzoic acid, γ-methacryloxypropyl trimethoxy silane, vinyltriacetoxysilane, vinyltrimethoxysilane, γ-isocyanatepropyl triethoxy silane, γ-glycidoxypropyl trimethoxy silane, β-(3,4-epoxycyclohexyl)ethyl trimethoxy silane, benzimidazoles and polybenzimidazoles, a lower hydroxyalkyl substituted pyridine derivative, a nitrogen heterocyclic compound, urea, thiourea, an organophosphorus compound, 8-oxyquinoline, 4-hydroxypteridine and derivativefs, 1,10-phenanthroline and derivatives, 2,2′-bipyridine and derivatives, benzotriazoles, organophosphorus compounds, phenylenediamine compounds, 2-amino-1-phenylethanol, N-phenylethanolamine, N-ethyldiethanolamine, N-ethylethanolamine and derivatives, benzothiazole, and a benzothiazoleamine salt having a cyclohexyl ring and a morpholine ring, 3-glycidoxypropyltrimethoxysilane, 3-glycidoxypropyltriethoxy silane, 3-mercaptopropyltrimethoxysilane, 3-mercaptopropyltriethoxy silane, 3-methacryloyloxypropyltrimethoxysilane, vinyl trimethoxysilane, combinations thereof, or the like.

Surface leveling agents may be added to some embodiments of the photoresist composition to assist a top surface of the photoresist layer 220 to be level, so that impinging light will not be adversely modified by an unlevel surface. In some embodiments, the surface leveling agents include fluoroaliphatic esters, hydroxyl terminated fluorinated polyethers, fluorinated ethylene glycol polymers, silicones, acrylic polymer leveling agents, combinations thereof, or the like.

The various components such as the polymer, the PACs and the crosslinkers, along with any desired additives or agents, are placed in a solvent in order to aid in the mixing and dispensing of the photoresist composition. To aid in the mixing and dispensing of the photoresist composition, the solvent is chosen at least in part based upon the materials chosen for the polymer as well as the PACs. In some embodiments, the solvent is chosen such that the polymer and the PACs can be evenly dissolved into the solvent and dispensed upon the layer to be patterned. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK).

The amount of solvent in the photoresist compositing may be from about 80 wt % to about 99 wt % by weight based upon the total weight of the composition as 100%. In some embodiments, the amount of solvent in the photoresist compositing may be from about 95 wt % to about 99 wt %.

Once added, the mixture is then mixed in order to achieve a homogenous composition throughout the photoresist composition to ensure that there are no defects caused by uneven mixing or nonhomogeneous composition of the photoresist. Once mixed together, the photoresist composition may either be stored prior to its usage or immediately.

Once ready, the photoresist composition is then applied onto the layer to be patterned, such as the material layer 210 to form the photoresist layer 220. Applying may be accomplished by any suitable method, including spin coating, spray coating, dip coating, doctor blading, or the like. In some embodiments, applying the photoresist composition is accomplished using a coating track, in which the photoresist composition is dispensed on the spinning substrate 202. During dispense, the substrate 202 may be spun at a speed of up to about 4,000 rpm, for example, from about 500 to about 3,000 rpm or from about 1,000 to about 2,500 rpm. In some embodiments, a thickness of the photoresist layer 220 may range from about 10 nm to about 300 nm.

Referring to FIGS. 1 and 2C, the method 100 proceeds to operation 106, in which a first baking process 230 is performed to the photoresist layer 220, in accordance with some embodiments. FIG. 2C is a cross-sectional view of the semiconductor device 200 of FIG. 2B after performing the first baking process 230 to the photoresist layer 220, in accordance with some embodiments.

Since this first baking process 230 is performed to cure and dry the photoresist layer 220 before exposing the photoresist layer 220 to radiation, the first baking process 230 may also be referred to as a pre-exposure-baking process. The curing and drying of the photoresist layer 220 removes the residue solvent and free volume from the film to make the photoresist layer 220 uniformly dense. In some embodiments, the first baking process 230 is performed at a temperature and time sufficient to cure and dry the photoresist layer 220. In some embodiments, the photoresist layer 220 is heated to a temperature ranging from about 40° C. to about 120° C. for about 10 seconds to about 10 minutes.

Referring to FIGS. 1 and 2D, the method 100 proceeds to operation 108, in which an exposure process 240 is performed to the photoresist layer 220, in accordance with some embodiments. FIG. 2D is a cross-sectional view of the semiconductor device 200 of FIG. 2C after performing the exposure process 240 to the photoresist layer 220, in accordance with some embodiments.

In some embodiments, the exposure process 240 is carried out by placing the photoresist-coating substrate in a photolithograph tool. The lithography tool includes a photomask 250, opticus, a light source to provide a radiation for exposure, and a movable stage for supporting and moving the substrate 202 under the exposure radiation.

During the exposure process 240, the photoresist layer 220 is exposed to the radiation from the light source through the photomask 250. In some embodiments, the photomask 250 is a transmissive mask. In some other embodiments, the photomask 250 is a reflective mask. The photomask 250 has a predefined pattern designed for an IC, based on a specification of the IC to be manufactured. The patterns of the photomask 250 correspond to patterns of materials that make up the various components of the IC device to be fabricated. For example, a portion of the IC design layout includes various IC features, such as an active region, gate electrode, source and drain, metal lines or vias of an interlayer interconnection, and openings for bonding pads, to be formed in the substrate 202 and/or the material layer 210 disposed on the substrate 202.

In some embodiments, the photomask 250 includes first regions 252 and second regions 254. In the first regions 252, the radiation is blocked by the photomask 250 to reach the photoresist layer 220, while in the second regions 254, the radiation is not blocked by the photomask 250 and can pass through the photomask 250 to reach the photoresist layer 220. As a result, portions of the photoresist layer 220 below the second regions 254 receive the radiation, referred to as exposed regions 220E, while portions of the photoresist layer 220 below the first regions 252 do not receive the radiation, referred to as unexposed regions 220U.

In some embodiments, the radiation is an EUV radiation (e.g., 13.5 nm). Alternatively, in some embodiments, the patterning radiation is a DUV radiation (e.g., from a 248 nm KrF excimer laser or a 193 nm ArF excimer laser), an X-ray radiation, an e-beam radiation, an ion beam radiation, or other suitable radiations. In some embodiments, the exposure process 240 is performed in a liquid (immersion lithography) or in a vacuum (e.g., for EUV lithography and e-beam lithography).

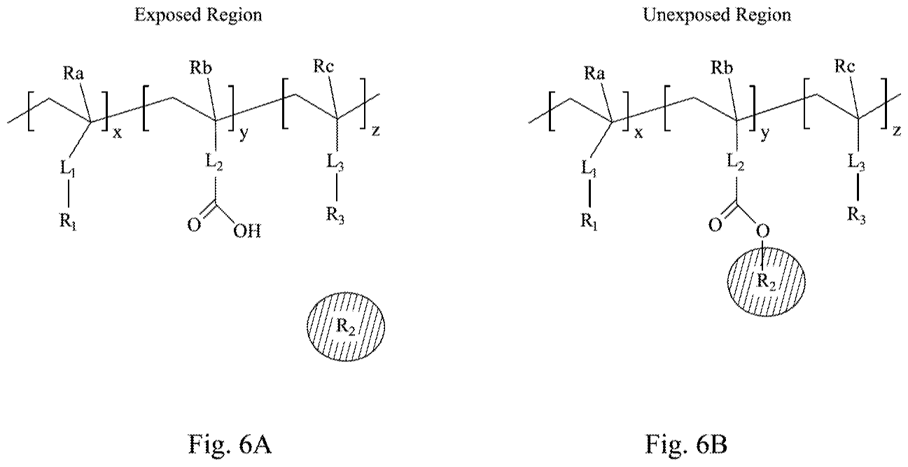

Upon elective (or patternwise) exposure to actinic radiation, the photoacid generator (PAG) in the exposed regions 220E of the photoresist layer 220 absorbs the radiation, which initiates the photoacid generator to generate an acid in the exposed regions 220E. The generated acid cleaves the acid labile group R₂ from the polymer (e.g., polymer of structure (I), (II), or (III)), forming a carboxy group in the exposed regions 220E, as shown in FIG. 6A, while the polymer (e.g., polymer of structure (I), (II) or (III)) the unexposed regions 220U remains intact, as shown in FIG. 6B. The formation of a carboxy group in the exposed region 220E renders the exposed region 220E more soluble in an aqueous-based developer, such as a tetramethylammonium hydroxy solution.

In some embodiments, the photoactive compounds include a photoinitiator that produces free radicals when exposed to actinic radiation, such as an EUV radiation having a wavelength of 13.5 nm or a UV or a radiation having a wavelength ranging from about 100 nm to about 1000 nm. The free radicals produced by the exposed photoinitiator cause the radical-active functional groups on one polymer chain to react with the thiol groups on another polymer chain, cause the radical-active functional groups in the crosslinker to react with thiol groups on two adjacent polymer chains, or cause the thiol groups in the crosslinker to react with radical-active functional groups on two adjacent polymer chains, thereby crosslinking the adjacent polymer chains in the exposed regions 220E during the subsequent baking process. Such crosslinking reaction increases the molecular weight of the polymer, which makes the exposed regions 220E less soluble in a developer. The increased molecular weight also leads to an increase in glass transition temperature Tg, which helps to reduce the acid diffusivity.

In some embodiments, the photoactive compound (PAC) in the photoresist composition includes two or more PACs, including a photoacid generator and a free radical producing photoinitiator. Exposure to actinic radiation causes the photoacid generator to generate an acid to cleave the acid labile group R₂ on the polymer and the photoinitiator to generate free radicals to cause the radical-active functional groups to crosslink. In some embodiments, the photoresist layer 220 is exposed to two different wavelengths of ultraviolet radiation, a first wavelength to activate the photoacid generator and a second wavelength to active the free-radical producing photoinitiator.

In some embodiments, where the photoactive compound (PAC) is a photoacid generator and the photoresist composition includes a thermal initiator for initiating the crosslinking reaction, an additional baking step is needed to activate the thermal initiator.

Referring to FIGS. 1 and 2E, the method 100 proceeds to operation 110, in which a second baking process 260 is performed to the photoresist layer 220, in accordance with some embodiments. FIG. 2E is a cross-sectional view of the semiconductor device 200 of FIG. 2D after performing the second baking process 260, in accordance with some embodiments.

Since the second baking process 260 is performed after the exposure process 240 that exposes the photoresist layer 220 to radiation, the second baking process 260 may also be referred to as a post-exposure-baking (PEB) process. The second baking process 260 helps to assist in the dispersing and reacting of the acid/base/free radical generated from the impingement of the radiation upon the PACs during the exposure. Such thermal assistance helps to create or enhance chemical differences between the exposed regions 220E and the unexposed regions 220U within the photoresist layer 220, causing differences in the solubility between the exposed regions 220E and the unexposed regions. Moreover, such thermal assistance facilitates the crosslinking reaction, and thus helps to further increase the crosslinking density and the molecular weight of the crosslinked polymer in either exposed regions 220E or unexposed regions 220U of the photoresist layer 220. The increased molecular weight results in a further increase in the (T_{g}) of the polymer. The high glass transition temperature arose from using thiol crosslinking allows effectively suppress the acid diffusion length during the photoresist lithography process, which helps to reduce line width roughness (LWR) of the resist pattern.

In instances where the photoresist composition includes a crosslinker and the crosslinking of the polymer is via a radical crosslinking reaction, the second baking process 260 may be performed at temperatures ranging from about 60° C. to about 150° C. If the temperature is greater than 150° C., the acid labile group R₂ in the polymer may decompose, which leads to photoresist malfunction.

In instances where the photoresist composition includes an oxidation agent and the crosslinking of the polymer is via oxidative disulfide formation, the second baking process 260 may be performed at temperatures ranging from about 50° C. about 150° C. If the temperature is greater than 150° C., the acid labile group R₂ in the polymer may decompose, which leads to photoresist malfunction.

In instances where the photoresist composition includes a thermal initiator, the second baking process 260 generates radicals from the thermal initiator by exposing the thermal initiator to heat. The generated radicals initiate the radical crosslinking reaction between the crosslinkers and the thiol or radical-active functional groups on the polymer, forming a crosslinked polymer in the unexposed region 220U. The second baking process 260 may be performed at temperatures ranging from about 50° C. about 150° C. If the temperature is greater than 150° C., the acid labile group R₂ in the polymer may decompose, which leads to photoresist malfunction.

Referring to FIGS. 1 and 2F, the method 100 proceeds to operation 112, in which a developing process 270 is performed to the photoresist layer 220, in accordance with some embodiments. FIG. 2F is a cross-sectional view of the semiconductor device 200 of FIG. 2E after performing the developing process 270 to the photoresist layer 220, in accordance with some embodiments.

The developing process 270 includes applying a developer to the photoresist layer 220. In some embodiments, during the developing process 270, the developer dissolves the radiation exposed regions 220E of a positive tone photoresist composition exposing the surface of the material layer 210, and leaving behind well-defined unexposed regions 220U having improved LWR than provided by conventional phenolic-based photoresist. In some embodiments, the developer dissolves the radiation unexposed regions 220U of a negative tone photoresist composition exposing the surface of the material layer 210, and leaving behind well-defined exposed regions 220E having improved LWR than provided by conventional phenolic-based photoresist.

After the developing process, a patterned photoresist layer 220P is formed. The patterned photoresist layer 220P includes the unexposed regions 220U of the photoresist layer (not shown) or the exposed regions 220E of the photoresist layer 220 as shown in (B) of FIG. 2F.

In some embodiments, the developer includes a solvent, and an acid or a base. In some embodiments, the concentration of the solvent in the developer is from about 60 wt % to about 99 wt % based on the total weight of the developer. The acid or base concentration is from about 0.001 wt % to about 20 wt % based on the total weight of the developer. In certain embodiments, the acid or base concentration in the developer is from about 0.01 wt % to about 15 wt % based on the total weight of the developer. In some embodiments, the developer is an aqueous-based developer, such as a tetramethylammonium hydroxide (TMAH) solution. In some embodiments the developer includes an organic solvent. In some embodiments, the developer is 2-heptanone or a butyl acetate such as n-butyl acetate.

In some embodiments, the developer is applied to the photoresist layer 220 using a spin coating process. In the spin coating process, the developer is applied to the photoresist layer 220 by a dispenser from above while the coated substrate 202 is rotated. In some embodiments, the developer is supplied at a rate of between about 5 ml/min and about 800 ml/min, while the coated substrate 202 is rotated at a speed of between about 100 rpm and about 2000 rpm. In some embodiments, the developer is at a temperature from about 100° C. to about 80° C. The development operation continues for between about 30 seconds to about 10 minutes in some embodiments.

While the spin coating operation is one suitable method for developing the photoresist layer 220 after exposure, it is intended to be illustrative and is not intended to limit the embodiment. Rather, any suitable development operations, including dip processes, puddle processes, and spray-on methods, may alternatively be used. All such development operations are included within the scope of the embodiments.

Referring to FIGS. 1 and 2G, the method 100 proceeds to operation 114, in which the material layer 210 is etched using the patterned photoresist layer 220P as an etch mask, in accordance with some embodiments. FIG. 2G is a cross-sectional view of the semiconductor device 200 of FIG. 2F after etching the material layer 210 using the patterned photoresist layer 220P as an etch mask, in accordance with some embodiments.

The material layer 210 is patterned, using the patterned photoresist layer 220P as shown in (A) of FIG. 2F as an etch mask, forming a patterned material layer 210P comprising recess 210a as shown in (A) of FIG. 2G, or using the patterned photoresist layer 220P as shown in (B) of FIG. 2F as an etch mask, forming a patterned material layer 210P comprising recess 210b as shown in (B) of FIG. 2G.

An etching process may be performed to transfer the pattern in the patterned photoresist layer 220P to the material layer 210. In some embodiments, the etching process employed is an anisotropic etch such as a dry etch although any suitable etch process may be utilized. In some embodiments, the dry etch is a reactive ion etch (RIE) or a plasma etch. In some embodiments, the dry etch is implemented by fluorine-containing gas (e.g., CF₄, SF₆, CH₂F₂, CHF₃, and/or C2F₆), chlorine-containing gas (e.g., C1₂, CHCl₃, CCl₄, and/or BCl₃), bromine-containing gas (e.g., HBr and/or CHBr₃), oxygen-containing gas, iodine-containing gas, other suitable gases and/or plasmas, or combinations thereof. In some embodiments, an oxygen plasma is performed to etch the material layer 210. In some embodiments, the anisotropic etch is performed at a temperature from about 250° C. to 450° C. for a duration from about 20 seconds to about 300 seconds.

If not completely consumed in the etching process, after formation of the patterned material layer 210P, the patterned photoresist layer 220P is removed, for example, by plasma ashing or wet stripping.

In the present disclosure, crosslinking polymer using thiol oxidation reaction or thiol-based radical “click” reaction allows for improved crosslinking efficiency comparing to conventional phenolic-based crosslinking reaction. The improved crosslinking efficiency facilitates the increase of the glass transition temperature (T_{g}) of the crosslinked polymer. As a result, the photoresist compositions of the present disclosure can effectively suppress the acid diffusion length, which leads to improved line width roughness (LWR) and enhanced resolution capable of reaching sub-22 nm feature sizes. The photoresist compositions and methods according to the present disclosure thus provide improved semiconductor device feature resolution and density with reduced defects in a higher efficiency process.

One aspect of this description relates to a photoresist composition. The photoresist composition includes a photoactive compound and a thiol-containing polymer having the following structure (I):

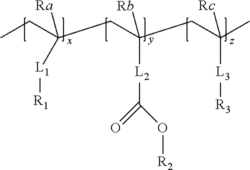

wherein L₁, L₂ and L₃ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers; R₁ is, at each occurrence, independently a C5-C20 aryl group, wherein the aryl is unsubstituted or substituted with a halogen, a carbonyl group, a hydroxyl group or Rₛ₁; R₂ is, at each occurrence, independently an acid liable group, wherein the acid liable group is unsubstituted or substituted with Rₛ₁; R₃ is, at each occurrence, independently a C1-C20 alkyl, C1-C20 heteroalkyl, C4-C20 cycloalkyl, C2-C30 heterocycloalky, C5-C20 aryl, C5-C20 heteroaryl or Rₛ₁ group; Rₛ₁ is SH, a C1-C20 thioalkyl, C3-C20 thiocycloalkyl, C1-C20 thiohydroxylalkyl, C2-C20 thioalkoxy, C3-C20 thioalkoxyl alkyl, C1-C20 thioacetyl, C2-C20 thioacetylalkyl, thiocarboxyl, C2-C20 thioalkyl carboxyl, C4-C20 thiocycloalkyl carboxyl, C3-C20 thiocarbocyclic or C3-C20 heterothiocyclic group; Rₐ, R_{b} and R_{c}are, at each occurrence, independently H or a C1-C3 alkyl group; and 0<x≤1, 0<y≤1, and 0≤z≤1, provided that one or more of R₁, R₂ and R₃ comprise Rₛ₁ such that the compound of structure (I) comprises at least one Rₛ₁.

Another aspect of this description relates to a photoresist composition. The photoresist composition includes an initiator; a photoacid generator; and a thiol-containing polymer having the following structure (II):

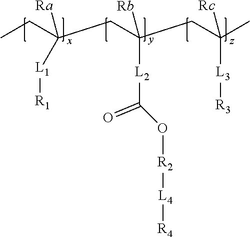

wherein L₁, L₂, L₃ and L₄ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers; R₁ is, at each occurrence, independently a C5-C20 aryl group, wherein the aryl is unsubstituted or substituted with a halogen, a carbonyl group, a hydroxyl group or Rₛ₁; R₂ is, at each occurrence, independently a divalent acid liable group; R₃ is, at each occurrence, independently a C1-C20 alkyl, C1-C20 heteroalkyl, C4-C20 cycloalkyl, C2-C30 heterocycloalkyl, C5-C20 aryl, C5-C20 heteroaryl or Rₛ₁ group; R₄ is, at each occurrence, independently a radical-active functional group comprising an alkene or alkyne group; Rₛ₁ is SH, a C1-C20 thioalkyl, C3-C20 thiocycloalkyl, C1-C20 thiohydroxylalkyl, C2-C20 thioalkoxy, C3-C20 thioalkoxyl alkyl, C1-C20 thioacetyl, C2-C20 thioacetylalkyl, thiocarboxyl, C2-C20 thioalkyl carboxyl, C4-C20 thiocycloalkyl carboxyl, C3-C20 thiocarbocyclic or C3-C30 heterothiocyclic group; Rₐ, R_{b} and R_{c} are, at each occurrence, independently H or a C1-C3 alkyl group; and 0<x≤1, 0<y≤1, and 0≤z≤1, provided that R₁, R₃, or both comprises Rₛ₁ such that the compound of structure (II) comprises at least one Rₛ₁.

Still another aspect of this description relates to a photoresist composition. The photoresist composition includes an initiator; a photoacid generator; a thiol-containing crosslinker comprising two or more thiol groups; and a thiol-free polymer having the following structure (III):

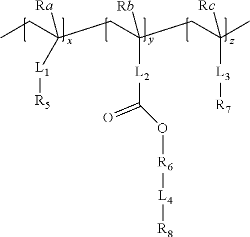

wherein L₁, L₂, L₃ and L₄ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers; R₅ is, at each occurrence, independently a C5-C20 aryl group, wherein the aryl is unsubstituted or substituted with a halogen, a carbonyl group or a hydroxyl group; R₆ is, at each occurrence, independently a divalent acid liable group; R₇ is, at each occurrence, independently a C1-C20 alkyl, C1-C20 heteroalkyl, C4-C20 cycloalkyl, C2-C30 heterocycloalkyl, C5-C20 aryl or C5-C20 heteroaryl group; R₈ is, at each occurrence, independently a radical-active functional group selected from an alkene or alkyne group; Rₐ, R_{b} and R_{c} are, at each occurrence, independently H or a C1-C3 alkyl group; and 0<x≤1, 0<y≤1, and 0≤z≤1.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A photoresist composition, comprising:
a photoactive compound; and
a thiol-containing polymer having the following structure (I): 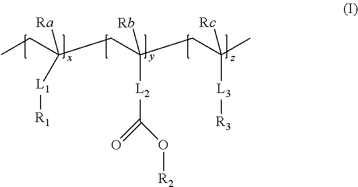
wherein:
L₁, L₂ and L₃ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers;
R₁ is, at each occurrence, independently a C5-C20 aryl group, wherein the aryl is unsubstituted or substituted with a halogen, a carbonyl group, a hydroxyl group or Rₛ₁;
R₂ is, at each occurrence, independently an acid liable group, wherein the acid liable group is unsubstituted or substituted with Rₛ₁;
R₃ is, at each occurrence, independently a C1-C20 alkyl, C1-C20 heteroalkyl, C4-C20 cycloalkyl, C2-C30 heterocycloalkyl, C5-C20 aryl, C5-C20 heteroaryl or Rₛ₁ group;
Rₛ₁ is SH, a C1-C20 thioalkyl, C3-C20 thiocycloalkyl, C1-C20 thiohydroxylalkyl, C2-C20 thioalkoxy, C3-C20 thioalkoxyl alkyl, C1-C20 thioacetyl, C2-C20 thioacetylalkyl, thiocarboxyl, C2-C20 thioalkyl carboxyl, C4-C20 thiocycloalkyl carboxyl, C3-C20 thiocarbocyclic or C3-C20 heterothiocyclic group;
Rₐ, R_{b} and R_{c} are, at each occurrence, independently H or a C1-C3 alkyl group; and
0<x≤1, 0<y≤1, and 0≤z≤1, provided that one or more of R₁, R₂ and R₃ comprise Rₛ₁ such that the compound of structure (I) comprises at least one Rₛ₁.

2. The photoresist composition of claim 1, wherein L₁, L₂ and L₃ are each a direct bond.

3. The photoresist composition of claim 1, wherein R₁ is a unsubstituted or Rₛ₁ substituted hydroxyphenyl, unsubstituted or Rₛ₁ substituted hydroxynaphthalenyl, unsubstituted or Rₛ₁ substituted hydroxyanthracenyl, unsubstituted or Rₛ₁ substituted phenyl, unsubstituted or Rₛ₁ substituted naphatahlenyl or unsubstituted or Rₛ₁ substituted anthracenyl group.

4. The photoresist composition of claim 1, wherein R₂ is, at each occurrence, independently a unsubstituted or Rₛ₁ substituted C4-C12 alkyl, unsubstituted or Rₛ₁ substituted C4-C12 cycloalkyl, unsubstituted or Rₛ₁ substituted C4-C12 hydroxyalkyl, unsubstituted or Rₛ₁ substituted C4-C12 alkoxy or unsubstituted or Rₛ₁ substituted C4-C12 alkoxy alkyl group, or a unsubstituted or Rₛ₁ substituted three-dimensional (3D) ring structure.

5. The photoresist composition of claim 1, wherein the thiol-containing polymer has one of the following structures (Ia), (Ib), (Ic) and (Id): 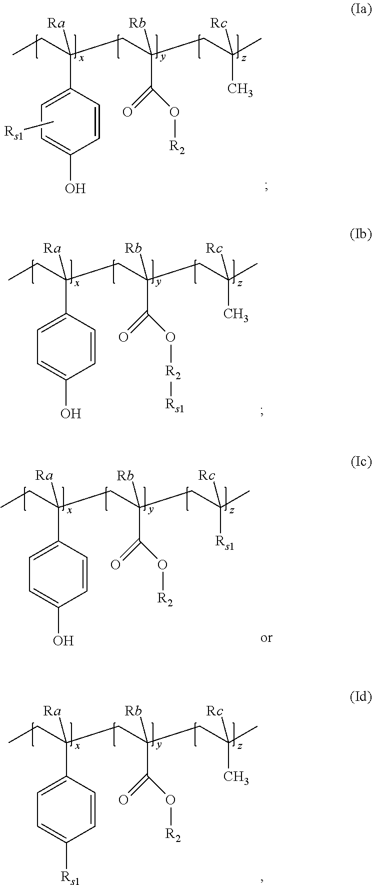
wherein R₂ is, at each occurrence, independently C4-C12 alkyl, C4-C12 cycloalkyl, C4-C12 hydroxyalkyl, C4-C12 alkoxy, C4-C12 alkoxy alkyl or a three-dimensional (3D) ring structure.

6. The photoresist composition of claim 5, wherein R₂ has one of the following structures:

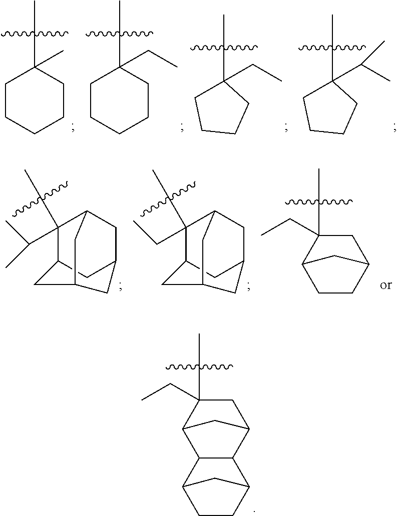

7. The photoresist composition of claim 6, wherein the thiol-containing polymer has one of the following structures (Ia-1), (Ib-2), (Ic-1) and (Id-1):

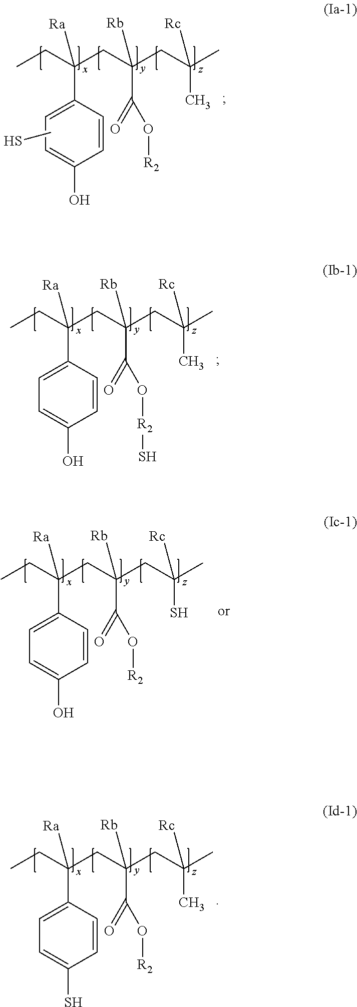

8. The photoresist composition of claim 1, further comprising an oxidation agent, wherein the oxidation agent comprises oxygen, H₂O₂, LiBrO₃, NaBrO₃, KBrO₃, O₃, I₂, or combinations thereof.

9. The photoresist composition of claim 8, further comprising an acid catalyst, wherein the acid catalyst comprises acetic acid (CH₃COOH), hydrochloric acid (HCl), carbonic acid (H₂CO₃), or combinations thereof.

10. The photoresist composition of claim 1, further comprising a crosslinker, wherein the crosslinker has one of the following structures:

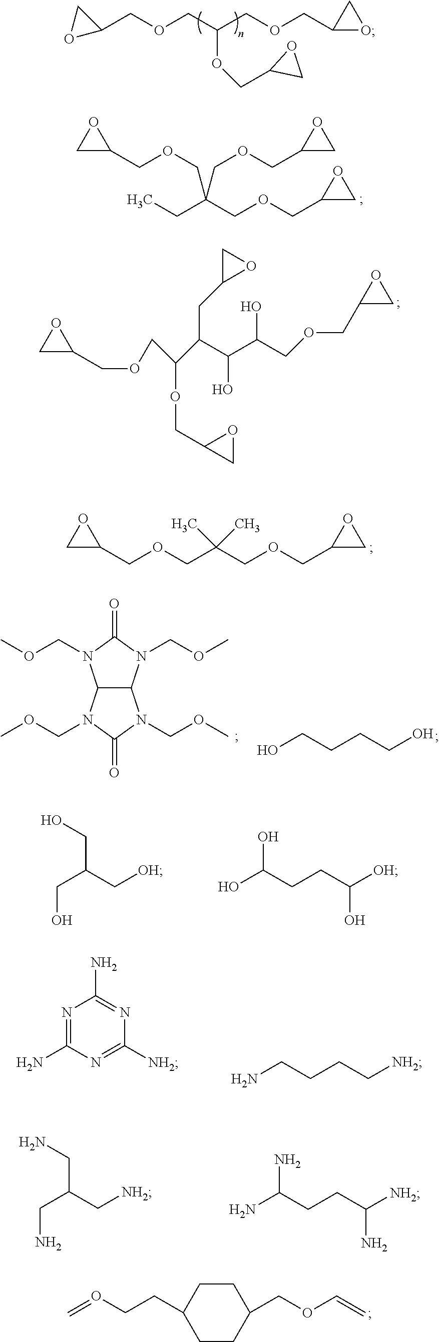

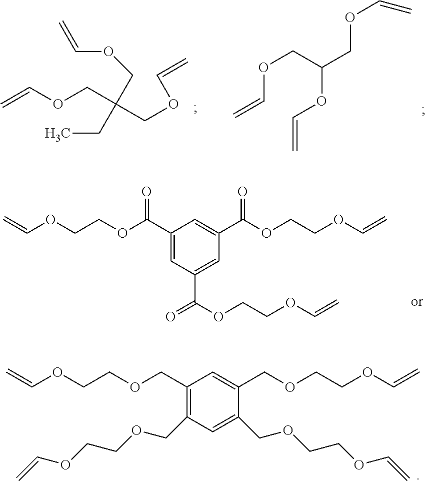

11. The photoresist composition of claim 1, wherein the photoactive compound comprises a photoacid generator, a photoinitiator or a combination thereof.

12. A photoresist composition, comprising:
an initiator;
a photoacid generator; and
a thiol-containing polymer having the following structure (II): 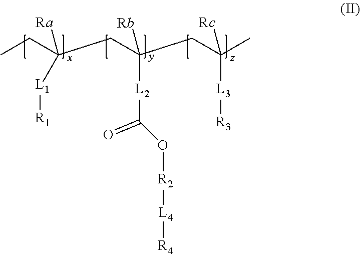
wherein:
L₁, L₂, L₃ and L₄ are, at each occurrence, independently a direct bond or oxy (—O—), carbonyl (—C(═O)—), carbonyloxy (—C(═O)—O—), oxycarbonyl (—O—C(═O)—), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers;
R₁ is, at each occurrence, independently a C5-C20 aryl group, wherein the aryl is unsubstituted or substituted with a halogen, a carbonyl group, a hydroxyl group or Rₛ₁;
R₂ is, at each occurrence, independently a divalent acid liable group;
R₃ is, at each occurrence, independently a C1-C20 alkyl, C1-C20 heteroalkyl, C4-C20 cycloalkyl, C2-C30 heterocycloalkyl, C5-C20 aryl, C5-C20 heteroaryl or Rₛ₁ group;
R₄ is, at each occurrence, independently a radical-active functional group comprising an alkene or alkyne group;
Rₛ₁ is SH, a C1-C20 thioalkyl, C3-C20 thiocycloalkyl, C1-C20 thiohydroxylalkyl, C2-C20 thioalkoxy, C3-C20 thioalkoxyl alkyl, C1-C20 thioacetyl, C2-C20 thioacetylalkyl, thiocarboxyl, C2-C20 thioalkyl carboxyl, C4-C20 thiocycloalkyl carboxyl, C3-C20 thiocarbocyclic or C3-C30 heterothiocyclic group;
Rₐ, R_{b} and R_{c} are, at each occurrence, independently H or a C1-C3 alkyl group; and
0<x≤1, 0<y≤1, and 0≤z≤1, provided that R₁, R₃, or both comprises Rₛ₁ such that the compound of structure (I) comprises at least one Rₛ₁.

13. The photoresist composition of claim 12, wherein the initiator comprises a photoinitiator, a thermal initiator, or a combination thereof.

14. The photoresist composition of claim 12, wherein L₁, L₂, L₃ and L₄ are each a direct bond.

15. The photoresist composition of claim 12, wherein R₂ is, at each occurrence, independently a unsubstituted or Rₛ₁ substituted C4-C12 alkyl, unsubstituted or Rₛ₁ substituted C4-C12 cycloalkyl, unsubstituted or Rₛ₁ substituted C4-C12 hydroxyalkyl, unsubstituted or Rₛ₁ substituted C4-C12 alkoxy or unsubstituted or Rₛ₁ substituted C4-C12 alkoxy alkyl divalent group, or a unsubstituted or Rₛ₁ substituted divalent three-dimensional (3D) ring structure.

16. The photoresist composition of claim 12, wherein the thiol-containing polymer has one of the following structures (IIa), (IIb) and (IIc): 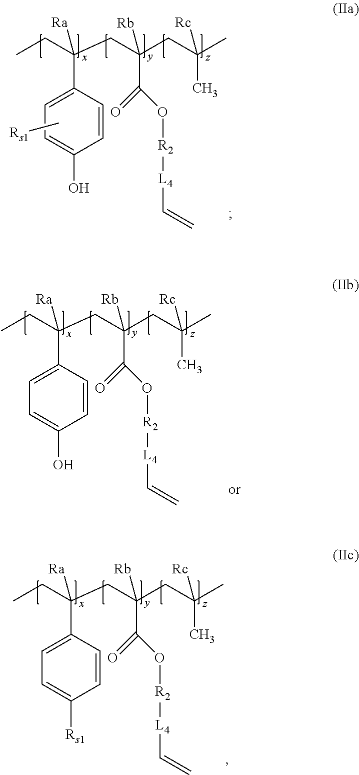
wherein R₂ is, at each occurrence, independently a C4-C12 alkyl, C4-C12 cycloalkyl, C4-C12 hydroxyalkyl, C4-C12 alkoxy or C4-C12 alkoxy alkyl divalent group, or a divalent three-dimensional (3D) ring structure.

17. The photoresist composition of claim 16, wherein the thiol-containing polymer has one of the following structures (IIa-1), (IIb-1) and (IIc-1):

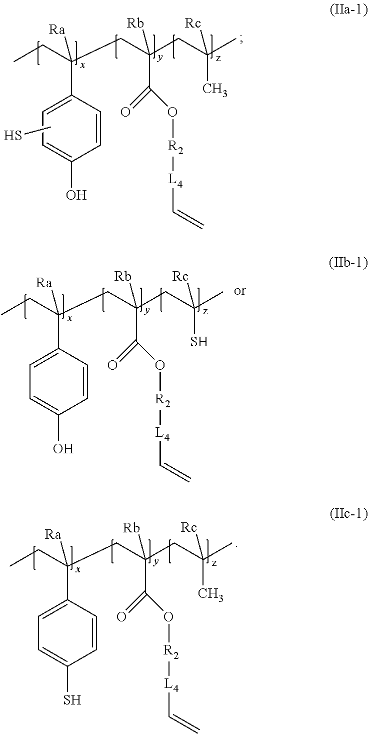

18. A photoresist composition, comprising:
an initiator;
a photoacid generator;
a thiol-containing crosslinker comprising two or more thiol groups; and
a thiol-free polymer having the following structure (III): 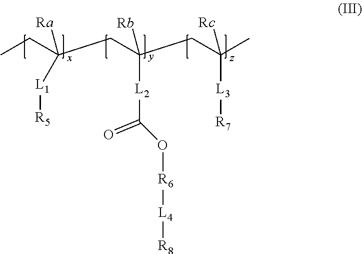
wherein:
L₁, L₂, L₃ and L₄ are, at each occurrence, independently a direct bond or oxy (—O—), carbonyl (—C(═O)—), carbonyloxy (—C(═O)—O—), oxycarbonyl (—O—C(═O)), carbonate (—O—C(═O)—O—), C1-C20 alkylene, C1-C20 heteroalkylene, C4-C20 cycloalkylene, C4-C20 heterocycloalkylene, C5-C20 arylene or C5-C20 heteroarylene linkers;
R₅ is, at each occurrence, independently a C5-C20 aryl group, wherein the aryl is unsubstituted or substituted with a halogen, a carbonyl group or a hydroxyl group;
R₆ is, at each occurrence, independently a divalent acid liable group;
R₇ is, at each occurrence, independently a C1-C20 alkyl, C1-C20 heteroalkyl, C4-C20 cycloalkyl, C2-C30 heterocycloalkyl, C5-C20 aryl or C5-C20 heteroaryl group;
R₈ is, at each occurrence, independently a radical-active functional group selected from an alkene or alkyne group;
Rₐ, R_{b} and R_{c} are, at each occurrence, independently H or a C1-C3 alkyl group; and
0<x≤1, 0<y≤1, and 0≤z≤1.

19. The photoresist composition of claim 18, wherein the thiol-free polymer has the following structure (IIIa): 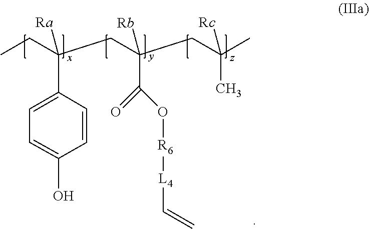
wherein R₆ is a C4-C12 alkyl, C4-C12 cycloalkyl, C4-C12 hydroxyalkyl, C4-C12 alkoxy or C4-C12 alkoxy alkyl divalent group, or a divalent three-dimensional (3D) ring structure.

20. The photoresist composition of claim 18, wherein the crosslinker has the following structure (IV): 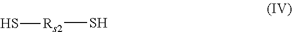
wherein Rₛ₂ is a C1-C20 alkylene, C1-C20 alkylene carboxyl, C3-C20 cycloalkylene carboxyl, C3-C20 saturated or unsaturated carbocyclic or C3-C20 heterocyclic group.
